(19) United States
(12) Patent Application Publication
(10) Pub. No.: US 2026/0291477 A1
(43) Pub. Date: Sep. 24, 2026

(54) DUAL-MODE CURRENT-MODE DRIVER

(71) Applicant: Alphawave IP Inc., Toronto (CA)

(72) Inventor: Joshua LIANG, Toronto (CA)

(21) Appl. No.: 19/554,421

(22) Filed: Mar. 2, 2026

Related U.S. Application Data
(60) Provisional application No. 63/775,233, filed on Mar. 20, 2025.

(51) Int. Cl. H03K 5/13; H03K 17/687

(52) U.S. Cl. CPC H03K 5/13; H03K 17/6872

(57) ABSTRACT

A driver circuit includes a tail transistor having a source coupled to a first power rail and a gate that is configured to receive a tail voltage, input transistors that have gates coupled to a pair of complementary input signals, wherein the sources of the input transistors are coupled to a drain of the tail transistor, cascode transistors, each cascode transistor being coupled between a drain of a corresponding input transistor and a second power rail, wherein, in response to the tail voltage at a first reference voltage level, the tail transistor causes a current flowing through the input transistors in a first mode of operation, and further where, in response to the tail voltage at a different voltage level, the tail transistor operates in triode mode in a second mode of operation.

### CROSS-REFERENCE TO RELATED APPLICATIONS

This application claims priority to and the benefit of Provisional Patent Application No. 63/775,233 that is titled “Timing Circuit” and filed in the U.S. Patent Office on Mar. 20, 2025, and is related to co-pending U.S. Patent Applications that is titled “Symmetric High-Speed Quadrature Divider With Feedforward Path And Sub-Rate Phase Detection” having Attorney Docket No. 2602878U1, filed concurrently herewith, assigned to the assignee hereof, and the entire content of these applications is expressly incorporated by reference herein.

### TECHNICAL FIELD

The present disclosure generally relates to a clock generation circuit and, more particularly, to circuitry for generating phase versions of clock signals.

### BACKGROUND

Electronic device technologies have seen explosive growth over the past several years. For example, growth of cellular and wireless communication technologies has been fueled by better communications, hardware, larger networks, and more reliable protocols. Wireless service providers are now able to offer their customers an ever-expanding array of features and services, and provide users with unprecedented levels of access to information, resources, and communications. To keep pace with these service enhancements, mobile electronic devices (e.g., cellular phones, tablets, laptops, etc.) have become more powerful and complex than ever. Wireless devices may include a high-speed bus interface for communication of signals between hardware components.

High-speed serial buses offer advantages over parallel communication links when, for example, there is demand for reduced power consumption and smaller footprints in integrated circuit (IC) devices. In a serial interface, data is converted from parallel words to a serial stream of bits using a serializer and is converted back to parallel words at the receiver using a deserializer. For example, the high-speed bus interface may be implemented using a Peripheral Component Interconnect Express (PCIe) bus, Universal Serial Bus (USB) or Serial Advanced Technology Attachment (SATA), among others.

IC devices may include a serializer/deserializer (SERDES) to transmit and receive through a communication link. In high-speed applications, timing of the operation of a SERDES may be controlled by multiple clock signals. The use of multiple increased frequency clock signals results in increased power consumption. Furthermore, the SERDES generally operates using clock signals that have the same frequency but different phases. Performance, accuracy or reliability of the SERDES may depend on frequency and the phase relationships of the clock signals and drift or other variations in the phase relationships of clock signals can result in errors in received or transmitted data. Therefore, there is an ongoing need for new drivers, circuits and techniques that provide reliable lower-power clock generation and calibration circuits for components used to receive clock signals over high-speed serial links.

### SUMMARY

Certain aspects of the disclosure relate to IC devices that include multimode driver circuits. In various aspects of the disclosure, a driver circuit includes a tail transistor having a source coupled to a first power rail and a gate that is configured to receive a tail voltage, input transistors that have gates coupled to a pair of complementary input signals, wherein the sources of the input transistors are coupled to a drain of the tail transistor, cascode transistors, each cascode transistor being coupled between a drain of a corresponding input transistor and a second power rail, wherein, in response to the tail voltage at a first reference voltage level, the tail transistor causes a current flowing through the input transistors in a first mode of operation, and further where, in response to the tail voltage at a different voltage level, the tail transistor operates in triode mode in a second mode of operation.

In various aspects of the disclosure, an apparatus has means for controlling current through a pair of input transistors, including a tail transistor and cascode transistors, means for configuring the tail transistor, wherein the tail transistor controls the current flowing through the pair of input transistors in a first mode of operation and operates in triode mode in a second mode of operation, and means for configuring the cascode transistors. The cascode transistors may control the current flowing through the pair of input transistors when the tail transistor is operating in triode mode.

In various aspects of the disclosure, a method for operating a multimode driver includes using a tail transistor to control current through a pair of input transistors in a first mode of operation, using cascode transistors to control the current through the pair of input transistors in a second mode of operation, providing a tail voltage to a gate of the tail transistor at a first reference voltage level that configures a current flowing through the input transistors in the first mode of operation, and driving the tail voltage to a voltage level that causes the tail transistor to operate in triode mode in the second mode of operation. The input transistors typically have gates coupled to a pair of complementary input signals.

In some aspects, the driver circuit includes a mode select circuit that is configured to provide the tail voltage to the tail transistor. The mode select circuit may include a feedback loop that defines a second reference voltage in the first mode of operation. The mode select circuit may be further configured to provide a third reference voltage to the gates of the cascode transistors in the second mode of operation.

In one aspect, the mode select circuit is further configured to provide a third reference voltage to the gates of the cascode transistors in the second mode of operation. The cascode transistors may control the current flowing through the input transistors in the second mode of operation. The mode select circuit may include a feedback loop that defines the third reference voltage in the first mode of operation.

### BRIEF DESCRIPTION OF THE DRAWINGS

FIG. 1 illustrates an example of a system-on-a-chip in accordance with certain aspects of the present disclosure.

FIG. 2 illustrates an apparatus employing interconnected chiplets.

FIG. 3 illustrates an example of a system that employs a multi-channel data communication link.

FIG. 4 illustrates an example of timing associated with a receiver that may be adapted or configured in accordance with certain aspects of this disclosure.

FIG. 5 illustrates an example of a quarter-rate transmitter.

FIG. 6 illustrates a first example of a serializer that may be adapted in accordance with certain aspects of this disclosure.

FIG. 7 illustrates an example of a clock generator that provides a multiphase output clock signal.

FIG. 8 illustrates a clock generator that has been configured or adapted in accordance with certain aspects of this disclosure.

FIG. 9 illustrates an example of dual input latch that may be configured in accordance with certain aspects of this disclosure.

FIG. 10 illustrates an example of a serializer circuit provided in a transmitter.

FIG. 11 illustrates an example of a phase detection circuit that may be implemented in accordance with certain aspects of this disclosure

FIG. 12 illustrates two driver circuits 1200, 1220 that can be used in CML-based interface circuits.

FIG. 13 illustrates a dual-mode CML driver that may be configured in accordance with certain aspects of this disclosure.

FIG. 14 is a flowchart of a method for generating clock signals in accordance with certain aspects of this disclosure.

FIG. 15 is a flowchart of a method for generating clock signals in accordance with certain aspects of this disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well-known structures and components are shown in block diagram form in order to avoid obscuring such concepts.

Several aspects of the invention will now be presented with reference to various apparatus and methods. These apparatus and methods will be described in the following detailed description and illustrated in the accompanying drawings by various blocks, modules, components, circuits, steps, processes, algorithms, etc. (collectively referred to as “elements”). These elements may be implemented using electronic hardware, computer software, or any combination thereof. Whether such elements are implemented as hardware or software depends upon the particular application and design constraints imposed on the overall system.

Data communication links employed by SoCs and other IC devices to connect processors with modems and other peripherals may be operated in accordance with industry or proprietary standards or protocols associated with certain functions or types of devices. According to certain aspects of the disclosure, a serial data link may be used to interconnect electronic devices that are subcomponents of an apparatus such as a cellular phone, a smart phone, a session initiation protocol (SIP) phone, a laptop, a notebook, a netbook, a smartbook, a personal digital assistant (PDA), a server, a data center, a satellite radio, a global positioning system (GPS) device, a smart home device, intelligent lighting, a multimedia device, a video device, a digital audio player (e.g., MP3 player), a camera, a game console, an entertainment device, a vehicle component, a wearable computing device (e.g., a smart watch, a health or fitness tracker, eyewear, etc.), an appliance, a sensor, a security device, a vending machine, a smart meter, a drone, a multicopter, or any other similar functioning device.

Certain aspects of the disclosure are applicable to input/out (I/O) circuits that provide an interface between core circuits and memory devices. Many mobile devices employ Synchronous Dynamic Random Access Memory (SDRAM), including Low-Power Double Data Rate SDRAM, which may be referred to as low-power DDR SDRAM, LPDDR SDRAM or, in some instances, LPDDRx where x describes the technology generation of the LPDDR SDRAM. Later generations of LPDDR SDRAM designed to operate at higher operating frequencies may employ lower voltage levels in the core of an SoC or memory device to mitigate for increased power associated with the higher operating frequencies.

Process technology employed to manufacture semiconductor devices, including IC devices is continually improving. Process technology includes the manufacturing methods used to make IC devices and defines transistor size, operating voltages and switching speeds. Features that are constituent elements of circuits in an IC device may be referred as technology nodes and/or process nodes. The terms technology node, process node, process technology may be used to characterize a specific semiconductor manufacturing process and corresponding design rules. Faster and more power-efficient technology nodes are being continuously developed through the use of smaller feature size to produce smaller transistors that enable the manufacture of higher-density ICs.

Certain examples of clock generation circuits are disclosed herein. Certain clock generation circuits are illustrated as being implemented using certain combinations of P-type metal-oxide-semiconductor (PMOS) transistors and N-type metal-oxide-semiconductor (NMOS) transistors. These circuits are provided by way of example only, and it is contemplated that the concepts disclosed herein can be implemented in circuits that use different combinations of NMOS and PMOS transistors. Circuits that include NMOS and PMOS transistors are typically coupled to the rails of a power supply. The power supply provides a current that flows from a higher voltage rail to a lower voltage rail. A rail may include some combination of conductors, wires, connectors and other types of interconnect. For the purposes of this description, the higher voltage rail may be referenced as “VDD” or “V_{DD}” and the lower voltage rail may be referred to as Ground. In some implementations, power may be provided to certain circuits through more than two rails.

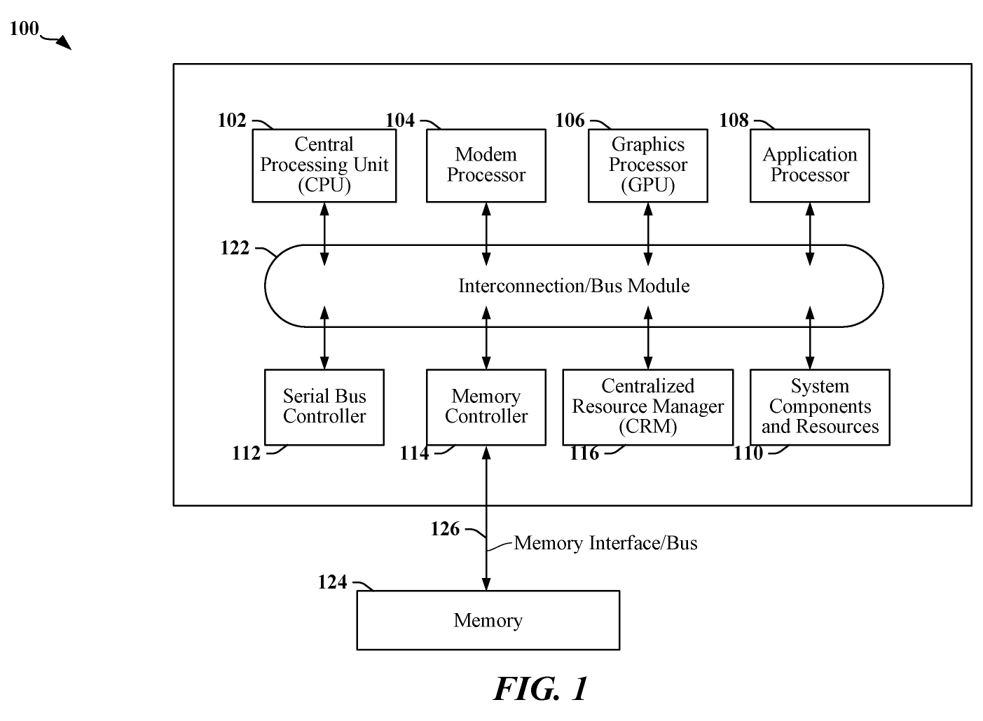

FIG. 1 illustrates an example of an apparatus 100 in which certain components and interconnections are implemented in an SoC. The SoC may include or be coupled to a memory interface/bus 126 that can be adapted according to certain aspects of the present disclosure. The apparatus 100 may include a number of heterogeneous processors, such as a central processing unit (CPU) 102, a modem processor 104, a graphics processor 106, and an application processor 108. Each processor 102, 104, 106, 108, may include one or more cores, and each processor/core may perform operations independent of the other processors/cores. The processors 102, 104, 106, 108 may be organized in close proximity to one another (e.g., on a single substrate, die, integrated chip, etc.) so that the processors may operate at a much higher frequency/clock rate than would be possible if the signals were to travel off-chip. The proximity of the cores may also allow for the sharing of on-chip memory and resources (e.g., voltage rails), as well as for more coordinated cooperation between cores.

The apparatus 100 may include system components and resources 110 for managing sensor data, analog-to-digital conversions, and/or wireless data transmissions, and for performing other specialized operations (e.g., decoding high-definition video, video processing, etc.). System components and resources 110 may also include components such as voltage regulators, oscillators, phase-locked loops (PLLs), peripheral bridges, data controllers, system controllers, access ports, timers, and/or other similar components used to support the processors and software clients running on the computing device. The system components and resources 110 may also include circuitry for interfacing with peripheral devices, such as cameras, electronic displays, wireless communication devices, external memory chips, etc.

The apparatus 100 may further include a serial bus controller 112 such as a Universal Serial Bus (USB) controller, one or more memory controllers 114, and a centralized resource manager (CRM) 116. The apparatus 100 may also include an input/output module (not illustrated) for communicating with resources external to the SoC, each of which may be shared by two or more of the internal SoC components.

The processors 102, 104, 106, 108 may be interconnected to the serial bus controller 112, the memory controller 114, system components and resources 110, CRM 116, and/or other system components via an interconnection/bus module 122, which may include an array of reconfigurable logic gates and/or implement a bus architecture. Communications may also be provided by advanced interconnects, such as high-performance networks on chip (NoCs).

The interconnection/bus module 122 may include or provide a bus mastering system configured to grant SoC components (e.g., processors, peripherals, etc.) exclusive control of the bus (e.g., to transfer data in burst mode, block transfer mode, etc.) for a set duration, number of operations, number of bytes, etc. In some cases, the interconnection/bus module 122 may implement an arbitration scheme to prevent multiple master components from attempting to drive the bus simultaneously. The memory controller 114 may be a specialized hardware module configured to manage the flow of data to and from a memory 124 via the memory interface/bus 126.

The memory controller 114 may comprise one or more processors configured to perform read and write operations with the memory 124. Examples of processors include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. In certain aspects, the memory 124 may be part of the apparatus 100.

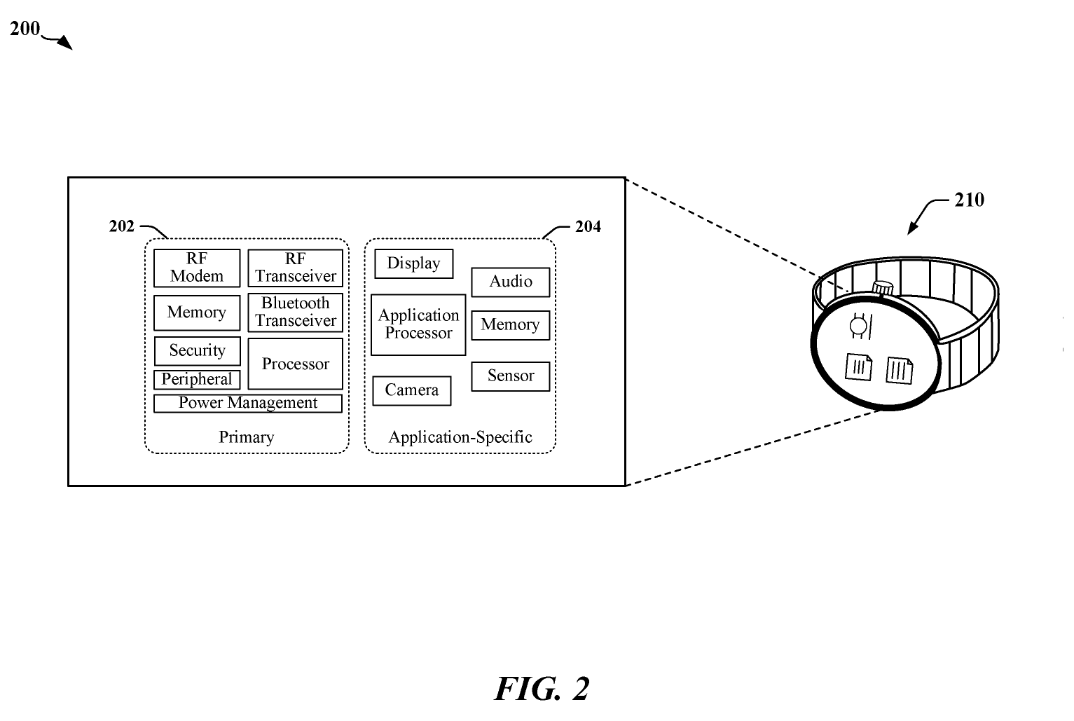

FIG. 2 illustrates an example of an apparatus 200 in which certain components are implemented using multiple chiplets that are interconnected using one or more data communication buses. In one example, the apparatus 200 may be enclosed within a wearable device a portable or wearable processing and/or communication device (each of which being referred to herein as a portable communication device or PCD), sensors, instruments, appliances and other such devices include one or more ICs. These devices may include mobile phones, tablet computers, palmtop computers, portable digital assistants (PDAs), portable game consoles, and other portable electronic devices such as the illustrated smartwatch 210. PCDs commonly contain integrated circuits or SoCs that include numerous components or subsystems designed to work together to deliver functionality to a user. The various SoC subsystems may communicate with each other via one or more intra-chip data buses or similar data communication interconnects. PCDs may have multiple SoCs that communicate with each other via similar inter-chip interconnects. The ICs are typically packaged in an IC package, which may be referred to as a “semiconductor package” or “chip package.” The IC package typically includes a package substrate and one or more IC chips or other electronic modules mounted to the package substrate to provide electrical connectivity to the IC chips. For example, an IC chip in an IC package may be configured as an SoC. The IC chips are electrically coupled to other IC chips and/or to other components in the IC package through electrical coupling to metal lines in the package substrate. The IC chips can also be electrically coupled to other circuits outside the IC package through electrical connections of external metal interconnects (e.g., solder bumps) of the IC package.

Chiplet technology can be used to address some of the performance, power and size design requirements for complex SoCs used in certain mobile or wearable devices. The block diagram in FIG. 2 illustrates certain aspects of an apparatus 200 that can be constructed using chiplets. The apparatus 200 may be configured by selecting a combination of chiplets that implement certain subsystems or distinct functional elements. In the illustrated example, the apparatus 200 includes a set of primary chiplets 202 that enable the apparatus 200 to perform core processing, security and communication functions. The set of primary chiplets 202 include a processor, memory and one or more modems. The illustrated apparatus 200 also includes a set of application-specific chiplets 204 that includes an application processor, display driver, camera interface and audio controller. In a remote sensing device or appliance, the audio-visual components could be omitted and may be replaced with analog-to-digital controllers, for example.

The apparatus 200 may include a variety of processing engines, such as central processing units (CPUs) with multiple cores, graphical processing units (GPUs), digital signal processors (DSPs), neural processing units (NPUs), wireless transceiver units (also referred to as modems), peripherals, display and imaging interfaces, etc. Each of these subsystems and other functional elements can be implemented as an individual chiplet, or as a combination of chiplets. The chiplets included in the apparatus 200 can be proprietary or may be acquired from a variety of sources. An SoC may be constructed from chiplets manufactured at different process nodes and/or operated at different voltages.

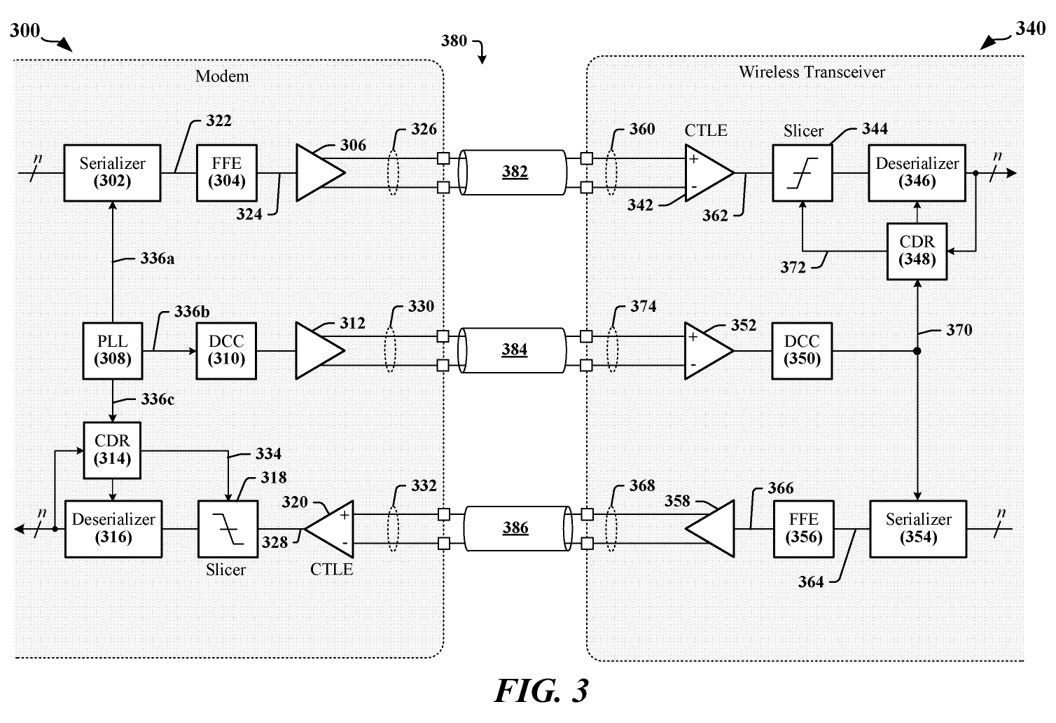

FIG. 3 illustrates an example of a system that employs a multi-channel data communication link 380 to couple a modem 300 with a wireless transceiver 340. The data communication link 380 includes data channels 382 and 386 and a clock channel 384 that provide a transmission medium through which signals propagate between devices. In the illustrated example, a modem 300 transmits data in a first signal over a first data channel 382 to a wireless transceiver 340 and receives data in a second signal transmitted over a second data channel 386. In the illustrated example, data signals are transmitted over the data channels 382 and 386 in accordance with timing information provided by a bus clock signal 330 transmitted over the clock channel 384. In other examples, data may be captured from data signals using a clock signal that is generated at the receiver and synchronized based on transitions in one or more data signals.

The modem 300 may include a serializer 302 configured to convert n-bit parallel data elements, bytes or words into a serial data stream for transmission in a transmit data signal 322 over the first data channel 382. The transmit data signal 322 may be preconditioned by a pre-equalizing circuit, such as the illustrated digital feed-forward equalizer (the FFE 304), in order to combat or compensate for signal distortions attributable to inter-symbol interference (ISI), reflection and other effects that can be expected to limit bandwidth in first data channel 382. The preconditioned transmit data signal 324 output by the FFE 304 is provided to a driver circuit 306 that is configured drive the first data channel 382.

The modem 300 may include a serializer 302 configured to convert n-bit parallel data elements, bytes or words into a serial data stream for transmission in a serialized data signal 322. The serialized data signal 322 may be preconditioned by a pre-equalizing circuit, such as the illustrated digital feed-forward equalizer (the FFE 304), in order to combat or compensate for signal distortions attributable to inter-symbol interference (ISI), reflection and other effects that can be expected to limit bandwidth in the first data channel 382. A preconditioned data signal 324 output by the FFE 304 is provided to a driver circuit 306 that is configured generate and transmit a differential transmit data signal 326 over the first data channel 382. For the purposes of this disclosure, a differential signal includes two complementary signals that are phase-shifted by 180° with respect to one another.

The wireless transceiver 340 can be configured to process a data signal 360 received over the first data channel 382. The data signal 360 may be provided to a differential receiver 342, which may include or cooperate with an equalizing circuit. In one example, continuous time linear equalization (CTLE) may be used to compensate for certain losses experienced in the first data channel 382. The first data channel 382may be characterized in some respects as a low-pass filter. In the illustrated example, the differential receiver 342 outputs an equalized data signal 362 that is sampled by a slicer 344. The slicer 344 may be implemented using a D-flipflop or the like and may be configured to capture signaling state of the equalized data signal 362 under the control of edges in a sampling clock signal 372 generated by a clock and data recovery (CDR) circuit 348. The output of the slicer 344 may be provided to a deserializer 346 that is clocked in accordance with one or more clock signals provided by the CDR circuit 348. The CDR circuit 348 may be configured to delay or phase shift a receiver clock signal 370 to ensure that edges in the sampling clock signal 372 are timed to optimize sampling reliability.

In the illustrated wireless transceiver 340, the receiver clock signal 370 is derived from a received bus clock signal 374 from the clock channel 384. A differential receiver 352 coupled to the clock channel 384 may be configured to equalize the received bus clock signal 374, and a duty cycle correction circuit 350 may be used to adjust the duty cycle of the receiver clock signal 370. The receiver clock signal 370 is provided to a serializer 354 that is configured to convert n-bit parallel data elements, bytes or words into a serial data stream for transmission in a serialized data signal 364. The serialized data signal 364 may be preconditioned by a pre-equalizing circuit, such as the illustrated FFE 356, in order to combat or compensate for signal distortions attributable to ISI, reflection and other effects that can be expected to limit bandwidth in the second data channel 386. A preconditioned data signal 366 output by the FFE 356 is provided to a driver circuit 358 that is configured generate and transmit a differential transmit data signal 368 over the second data channel 386.

The illustrated modem 300 can be configured to process a data signal 332 received over the second data channel 386. The data signal 332 may be provided to a differential receiver 320, which may include or cooperate with an equalizing circuit. In one example, CTLE may be used to compensate for certain losses experienced in the second data channel 386. The second data channel 386 may be characterized in some respects as a low-pass filter. In the illustrated example, the differential receiver 320 outputs an equalized data signal 328 that is sampled by a slicer 318. The slicer 318 may be implemented using a D-flipflop or the like and may be configured to capture signaling state of the equalized data signal 328 under the control of edges in a sampling clock signal 334 generated by a CDR circuit 314. The output of the slicer 318 may be provided to a deserializer 316 that is clocked in accordance with one or more clock signals provided by the CDR circuit 314. The CDR circuit 314 may be configured to delay or phase shift a transmitter clock signal to ensure that edges in the sampling clock signal 334 are timed to optimize sampling reliability.

A clock generation circuit, including the illustrated phase locked loop 308, may generate multiple clock signals 336a, 336b, 336c used by the modem 300. One or more of the clock signals 336a, 336b, 336c may be a divided version of a base clock signal generated by the PLL 308. One or more of the clock signals 336a, 336b, 336c may be phase shifted with respect to the base clock signal. In one example, the serializer 302 may produce the serialized data signal 322 using timing provided by a first clock signal 336a. In another example, the bus clock signal 330 transmitted over the clock channel 384 may be derived from a second clock signal 336b. In some instances, a duty cycle correction circuit 310 may be used to adjust the duty cycle of the second clock signal 336b and to provide an input to a driver circuit 312 that is configured drive the clock channel 384. In another example, the CDR circuit 348 may generate the sampling clock signal 334 from a third clock signal 336c.

Limiting power consumption presents a major challenge in communication interfaces, including communication interfaces that include a SERDES. In mobile communication devices, reducing power consumption can increase battery life between charges. Accordingly, power consumption is a parameter that must be considered when physical layer (PHY) circuits are designed for communication interfaces that are required to meet ever-increasing demands for data rates and corresponding signaling rates associated with the communication interface. Demands for higher data rates and increased performance from SERDES-based PHY circuits are a consequence of continual advances in process technology and changing industry and proprietary standards. Moreover, PHY circuits are typically required to maintain backward compatibility to all previous generations of technology while supporting the higher data rates required by ever-evolving standards, necessitating increased numbers of transistors. The switching frequency of PHY circuits in communication interfaces can be a major factor in power consumption of an apparatus. For example, the operating frequencies of clock generation circuits for SERDES-based PHY circuits are determinative of maximum data rates for an application and power consumption increases as operating frequencies increase.

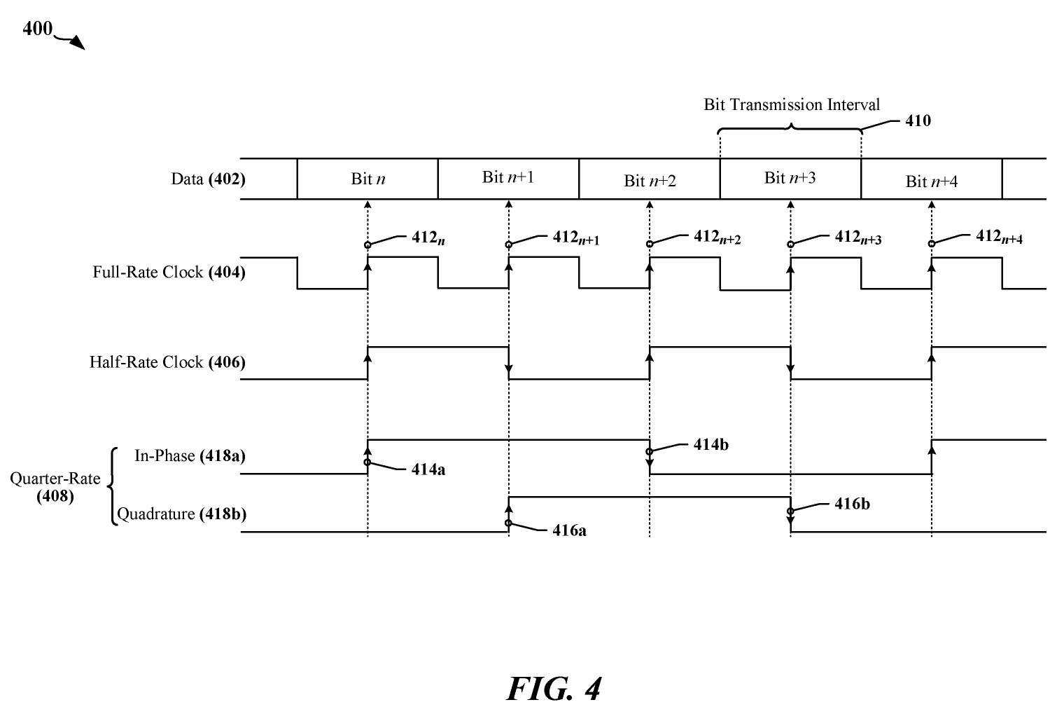

Power consumption can be reduced when certain SERDES circuits are operated in accordance with clock signals that have a frequency that is lower than the frequency of the data signal transmitted over a communication link. FIG. 4 illustrates an example of timing 400 associated with a receiver that may be adapted or configured in accordance with certain aspects of this disclosure. The illustrated timing 400 relates to a data signal 402 that is received over a communication link. Data bits are transmitted in bit transmission intervals 410 that have a duration defined by the frequency of the data signal 402. The frequency of the data signal defines the bit transmission rate defined for a single wire or channel of the communication link.

Certain SERDES circuits may be operated or controlled by a full-rate clock signal 404. The full-rate clock signal 404 has a period that matches the duration of each bit transmission interval 410 (i.e., the duration of transmission of each of Bit n – Bit n+4). A SERDES circuit that operates at full rate is required to meet certain timing requirements defined for the data signal 402. In one example, a single bit of data is shifted out of a full-rate serializer in every cycle of the full-rate clock signal 404. In another example, a receiver may be configured to sample or capture data using one edge of a full-rate clock signal. In the illustrated example, data bits may be captured using rising edges of the full-rate clock signal 404. In some instances, the full-rate clock signal 404 is phase shifted with respect to the data signal 402 to provide rising edges in the full-rate clock signal 404 at desired sampling points 412n-412n₊₄. In the illustrated example, rising edges of the full-rate clock signal 404 are timed to occur at the midpoint of each bit transmission interval 410. In other examples, the falling edges of the full-rate clock signal 404 may be used to capture data bits. In some implementations, data bits are captured toward the end of each bit transmission interval 410.

Certain SERDES circuits may be operated or controlled by a half-rate clock signal 406. The term half-rate as used herein refers to the use of a clock signal with a frequency that is half the frequency of the data signal 402. In the illustrated example, both rising and falling edges in the half-rate clock signal 406 are used to capture bits of data from different bit transmission intervals 410. The half-rate clock signal 406 has a period that is twice the duration of each bit transmission interval 410, and a data bit may be captured during each half-cycle of the half-rate clock signal 406. In the illustrated example, the rising edges and falling edges of the half-rate clock signal 406 are timed to occur at the midpoint of each bit transmission interval 410. In other examples, data bits may be captured toward the end of each bit transmission interval 410. A half-rate transmitter may include a serializer with two transmission paths that alternate in providing bits for transmission. The serializer may include one or more multiplexers, one or more shift registers, or some combination of multiplexers and shift registers. The circuits in the two transmission paths in a half-rate serializer may be clocked by different edges in the half-rate clock signal 406 and a multiplexer operating at the full-rate frequency may be used to select between outputs of the two transmission paths to provide a serial bitstream for transmission over a communication link. A half-rate receiver typically includes two receiver paths that alternate in sampling or capturing bits from the data signal 402. In one example, circuits in the half-rate receiver may include shift registers that respond to different edges in the half-rate clock signal 406.

Certain SERDES circuits may be operated or controlled by a quarter-rate clock 408. The term quarter-rate as used herein refers to the use of a multiphase clock signal with a frequency that is a quarter of the frequency of the data signal 402. The quarter-rate clock 408 includes an in-phase signal 418a and a quadrature signal 418b. The quadrature signal 418b is phase-shifted with respect to the in-phase signal 418a by 90°. Four consecutively transmitted data bits can be captured from different bit transmission intervals 410 in the data signal 402 using rising edges 414a in the in-phase signal 418a, rising edges 416a in the quadrature signal 418b, falling edges 414b in the in-phase signal 418a and falling edges 416b in the quadrature signal 418b. The quarter-rate clock 408 has a period that corresponds to four times the duration of each bit transmission interval 410, and a data bit is captured during each quarter-cycle of the quarter-rate clock 408. In the illustrated example, rising edges 414a, 416a and falling edges 414b, 416b are timed to occur at the midpoint of each bit transmission interval 410. In other examples, data bits may be captured toward the end of each bit transmission interval 410.

A quarter-rate transmitter may include a serializer with four transmission paths that alternate in providing bits for transmission. The serializer may include one or more multiplexers, one or more shift registers, or some combination of multiplexers and shift registers. The circuits in the four transmission paths in a quarter-rate serializer may be clocked by different edges provided by the in-phase signal 418a and the quadrature signal 418b. In one example, a multiplexer operating at the full-rate frequency may be used to select among the outputs of the four transmission paths to provide a serial bitstream for transmission over a communication link. A quarter-rate receiver may include four receiver paths that are configured to sample or capture bits from the data signal 402. In one example, circuits in the quarter-rate receiver may include shift registers or multiplexers that respond to different edges in the in-phase signal 418a and the quadrature signal 418b.

The generation of multiphase signals, such as the quarter-rate clock 408, requires precise quadrature clock generation to produce the 4 phases of a clock signal. Phase relationships between in-phase and quadrature signals can be affected by variations in operating conditions attributable to manufacturing process, circuit supply voltage, and die temperature (PVT). For example, the comparison of signals with reference signals depends on the stability or predictability of operational amplifiers (Op Amps), comparators, amplifiers and circuits that generate the reference signals. In some applications, it may be sufficient to optimize circuits for PVT corners or worst-case operating conditions. For the purposes of this disclosure, PVT corners represent limits of process, voltage, or temperature and/or combinations thereof. PVT corners may be correlated with limits of operational characteristics of a circuit, including current, voltage, temperature, switching frequency, rise time, fall time, settling time and other characteristics. In other applications it may be necessary to calibrate, recalibrate or reconfigure circuits to accommodate changing operating conditions

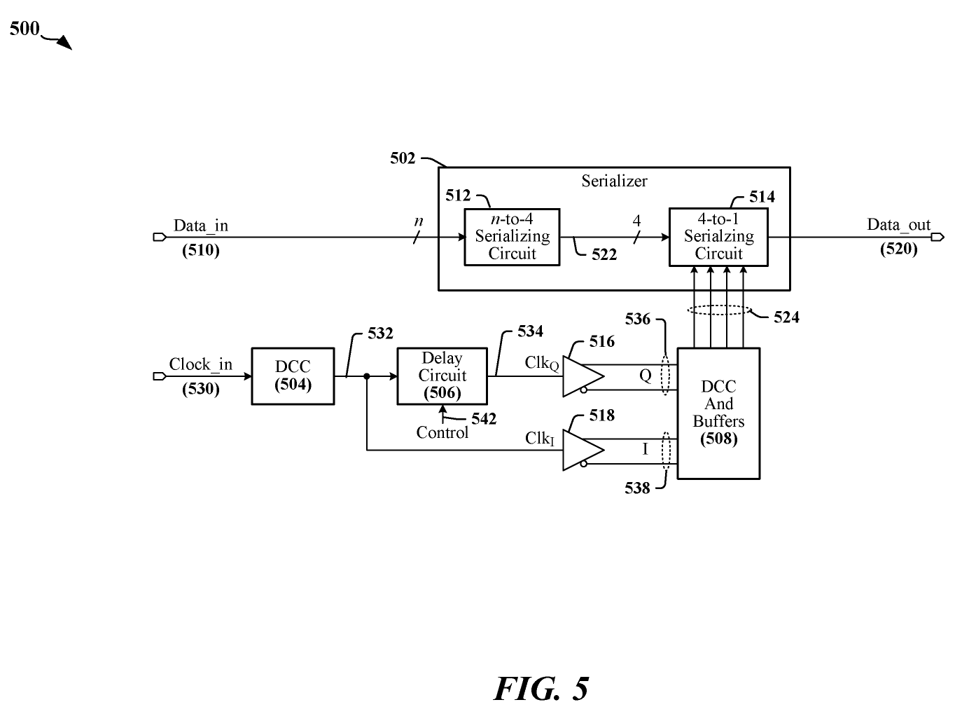

FIG. 5 illustrates an example of a quarter-rate transmitter 500. The quarter-rate transmitter 500 includes a serializer 502 that responds to edges provided in a multiphase clock signal 524 to provide a data output signal 520 that includes a serial bitstream. The serial bitstream is obtained by serializing a multibit data input 510. In the illustrated example, the multibit data input 510 is provided to a first serializing circuit 512 that receives a quantity (n) of bits and provides a 4-bit datastream 522 that includes a sequence of 4-bit units of data. In some implementations, the 4-bit datastream 522 may be generated using one or more multiplexers, one or more shift registers, or some combination of multiplexers and shift registers. In some implementations, the 4-bit datastream 522 may be received from registers written by a processor. The 4-bit datastream 522 is provided to a second serializing circuit 514 that provides a serial output data signal 520 according to timing provided by edges in the multiphase clock signal 524.

The multiphase clock signal 524 is derived from a quarter-rate input clock signal 530. In the illustrated example, the quarter-rate input clock signal 530 is provided to a duty cycle correction (DCC) circuit 504 that can be configured to ensure that the duration between rising edges and subsequent falling edges in a corrected clock signal 532 is substantially the same (i.e., within predefined tolerances) as the duration between falling edges and subsequent rising edges in the corrected clock signal 532. In some implementations, a divider circuit that provides the quarter-rate input clock signal 530 may be configured to ensure that the duty cycle of the quarter-rate input clock signal 530 lies within tolerances defined for the quarter-rate transmitter 500.

The corrected clock signal 532 may be provided to a buffer circuit 518 that outputs a differential in-phase clock signal 538. The corrected clock signal 532 is further provided to a delay circuit 506 that outputs a delayed clock signal 534. The delay circuit 506 can be configured by a control signal 542 to delay the corrected clock signal 532 by a duration the corresponds to 25% of the period of the quarter-rate input clock signal 530 in order to cause the delayed clock signal 534 to be phase-shifted by 90° with respect to the corrected clock signal 532. The delayed clock signal 534 may be provided to a buffer circuit 516 that outputs a differential quadrature clock signal 536. In one example, the delay duration provided by the delay circuit 506 may be selected or adjusted using a coded value provided by the control signal 542. In another example, the control signal 542 may provide feedback that adjusts the delay duration provided by the delay circuit 506.

The differential in-phase clock signal 538 (I) and the differential quadrature clock signal 536 (Q) may be provided to conditioning circuits 508. The conditioning circuits 508 may include clock distribution drivers, buffers, additional DCC circuits and the like. The conditioning circuits 508 output the multiphase clock signal 524.

Improvements in technology permit the transmission of serial data over a communication link at higher data rates using clock signals that can exceed 128 gigahertz (128 GHz). Data rates of 128 gigabits per second (128Gbps) may be supported using multiphase clock signals derived from the quarter-rate input clock signal 530. In some instances, an 8-phase clock signal may be used to reduce power consumption and enable relaxed timing specifications to be used in an IC device.

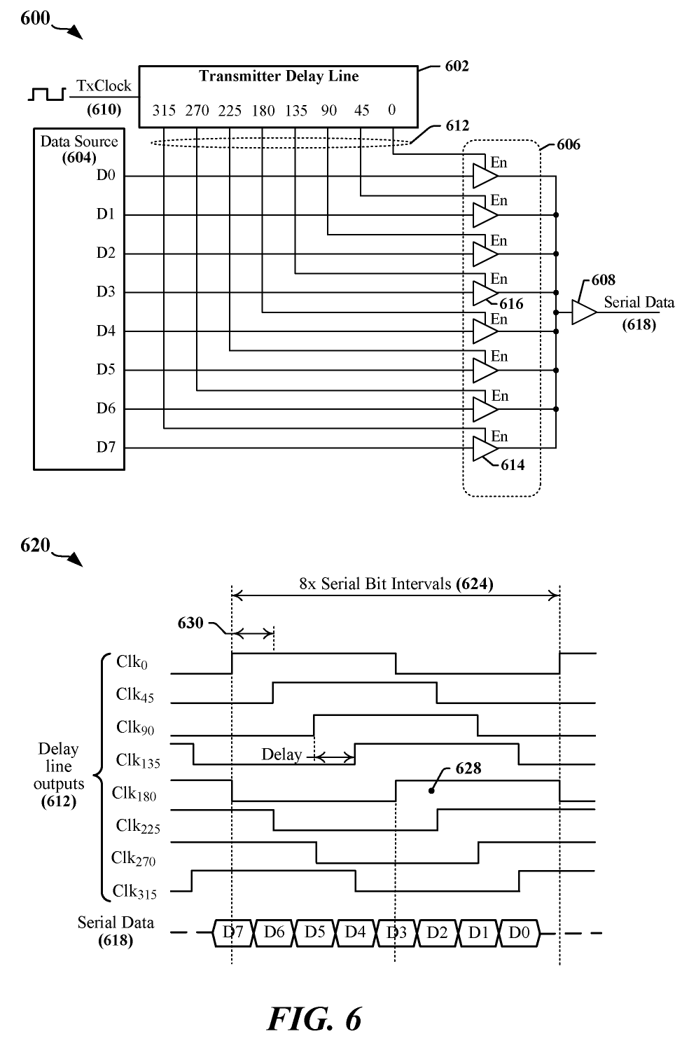

FIG. 6 illustrates an example of a serializer 600 that may be adapted in accordance with certain aspects of this disclosure. FIG. 6 includes a timing diagram 620 that illustrates certain aspects of the timing of signals generated or used by the serializer 600 in FIG. 6. The serializer 600 includes a delay line 602 and a set of buffers 606. The delay line 602 outputs eight delayed versions of a signal in response to edges in a transmit clock signal (TxClock 610) that is coupled to the input of the delay line 602. TxClock 610 may have a period 624 that corresponds to eight bit-transmission intervals 630.

Each of the delay line outputs 612 serves as an enable signal to one of the set of buffers 606. As a leading edge in TxClock 610 propagates through the delay line 602, a pulse is provided at each of the delay line outputs 612 in sequence. Nominally, at any given time only one of the delay line outputs 612 is high or otherwise in an active state. When one of the delay line outputs 612 is high or otherwise in an active state, a corresponding one of the set of buffers 606 is turned on and drives the input of a line driver 608. The line driver 608 is configured to drive the serial data line 618. In the illustrated serializer 600, each buffer in the set of buffers 606 is implemented using a tri-state buffer that has an input, an output and an enable input. The output of each buffer follows the input when the buffer is enabled. The output of each buffer is in a high impedance state when the buffer is disabled.

In one example, the Dly₇ output of the delay line 602 is coupled to an enable input of buffer 614 in the set of buffers 606 and a pulse 626 on the Dly₇ output selects the D7 data bit provided by the data source 604 for transmission over the serial data line 618. In another example, the Dly₃ output of the delay line 602 is coupled to an enable control input of buffer 616 in the set of buffers 606 and a pulse 628 on the Dly₃ output selects the D3 data bit provided by the data source 604 for transmission over the serial data line 618. The delay line outputs 612 operate to control the set of buffers 606 such that each bit from the data source 604 is sequentially transmitted over the serial data line 618, as illustrated by the signal transmitted on the serial data line 618 shown in FIG. 6. Of the data source 604, the set of buffers 606 and the line driver 608, only the line driver 608 is actively switching for all of the transmission of the 8-bit serial data.

In a general N:1 high-speed serializer, including the serializer 600, high-speed clock signals are used to generate a single transmitted signal by serializing an N-bit parallel bitstream. Delay and jitter can be minimized on the highest frequency clock signal through the use of lower frequency clock signals to process portions of the N-bit parallel data. The lower frequency clock signals may be generated by dividing and delaying the highest frequency clock signal. Phase detection and delay adjustment by means of phase interpolators or rotators can then be used to align clock signals.

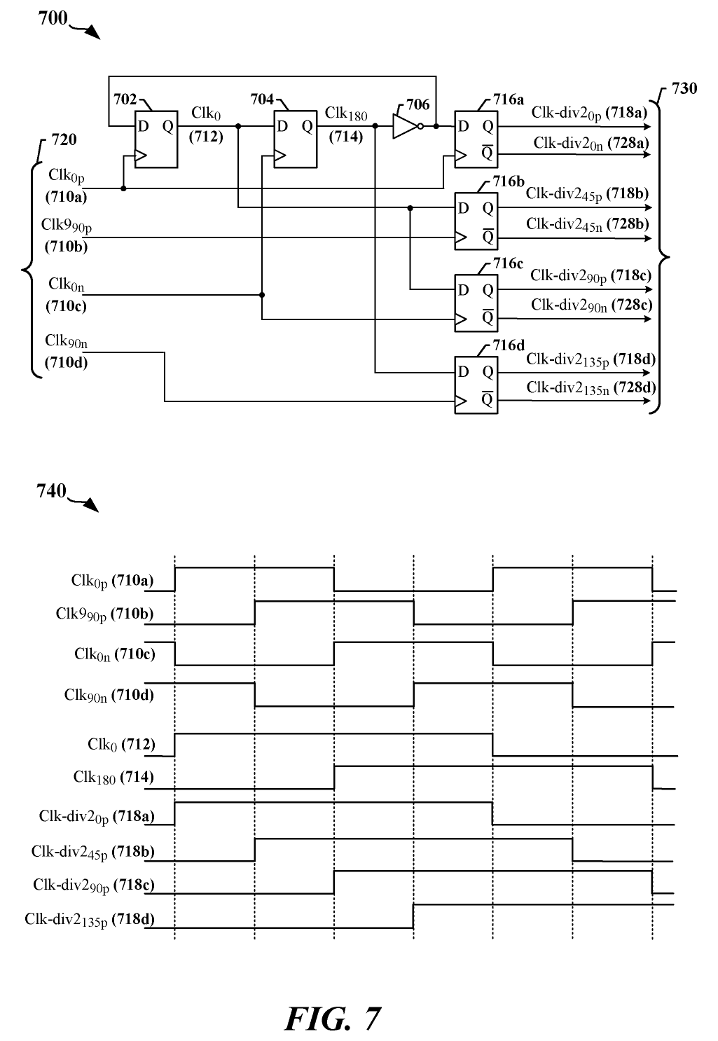

FIG. 7 illustrates an example of a clock generator 700 that provides a multiphase output clock signal 730. The timing diagram 740 illustrates the relationship between an input clock signal 720, intermediate signals 712, 714 and the output clock signal 730. The clock generator 700 is implemented using a single-loop divider that receives a multiphase input signal 720 that includes quadrature clock signals and their complements. The clock generator 700 outputs an 8-phase output at half the frequency of an input signal 720. In one example, a transmitter circuit coupled to a communication link that operates using a 128 GHz transmitter clock signal can use eight phase signals 718a-718d, 728a-728d to control portions of the transmitter circuit that can be switched at lower frequencies that a 128 GHz. For example, some circuits may be switched at 16 GHz rather than operating at the 128 GHz frequency of the transmitter clock signal.

In the illustrated example, the output clock signal 730 is derived from a multi-phase quarter-rate input clock signal 720. In one example, the input clock signal 720 includes complementary input phase signals. In the illustrated example, the clock generator 700 receives the Clk₀ₚsignal 710a and the Clk₀ₙ signal 710c that correspond to the differential in-phase clock signal 538 (I) shown in FIG. 5, and the Clk₉₀ₚ signal 710b and the Clk₉₀ₙ signal 710d that correspond to the differential quadrature clock signal 536 (Q).

The clock generator 700 may be characterized as a latch-based clock generator. In the illustrated example, the Clk₀ₚ signal 710a is used to clock or trigger a first divider latch 702 and the complementary Clk₀ₙsignal 710c is used to clock or trigger a second divider latch 704. The output of the first divider latch 702 (i.e., the Clk₀signal 712) drives the input of the second divider latch 704. The output of the second divider latch 704 (i.e., the Clk₁₈₀ signal 714) is coupled to the input of the first divider latch 702 through an inverter 706, completing a feedback loop. When settled, the Clk₀ signal 712 and the Clk₁₈₀ signal 714 oscillate at half the frequency of the Clk₀ₚ signal 710a.

The 8 phase signals 718a-718h may be generated by latches 716a-716d. Resampling latch 716a is effectively a mirror of the first divider latch 702, being clocked or triggered by the Clk₀ₚ signal 710a and receiving the inverted output of the second divider latch 704. Resampling latch 716a provides the in-phase output clock signal (i.e., the Clk-div2₀ₚsignal 718a) and the 180° phase-shifted output clock signal (i.e., the Clk-div2₀ₚ signal 728a). Resampling latch 716c is effectively a mirror of the second divider latch 704, being clocked or triggered by the Clk₀ₙsignal 710c and receiving the Clk₁₈₀ signal 714. Resampling latch 716c provides the 90° phase-shifted output clock signal (i.e., the Clk-div2₉₀ₚsignal 718c) and the 270° phase-shifted output clock signal (i.e., the Clk-div2₉₀ₙsignal 728c). Resampling latch 716b is clocked or triggered by the Clk₉₀ₚ signal 710b and receives the Clk₀ signal 712. Resampling latch 716b provides the 45° phase-shifted output clock signal (i.e., the Clk-div2₄₅ₚ signal 718b) and the 225° phase-shifted output clock signal (i.e., the Clk-div2₄₅ₙ signal 728b). Resampling latch 716d is clock or triggered by the Clk₉₀ₙ signal 710d and receives the Clk₁₈₀ signal 714. Resampling latch 716d provides the 135° phase-shifted output clock signal (i.e., the Clk-div2₁₃₅ₚ signal 718d) and the 315° phase-shifted output clock signal (i.e., the Clk-div2₁₃₅ₙ signal 728d).

Certain aspects of this disclosure relate to circuits, systems and methods that can align clock signals used in high-speed serial interfaces. In one aspect, a clock generating circuit implemented in accordance with certain aspects of this disclosure provides feedforward paths that can improve latch operation. For example, the latches can effectively operate at higher frequencies when feedforward paths are provided. A clock divider circuit can operate at higher frequencies in a given technology node when the feedforward paths preemptively satisfy setup and hold times, enabling operation of the transmitter at increased data rates. In another aspect, a phase detector circuit implemented in accordance with certain aspects of this disclosure can facilitate clock signal alignment.

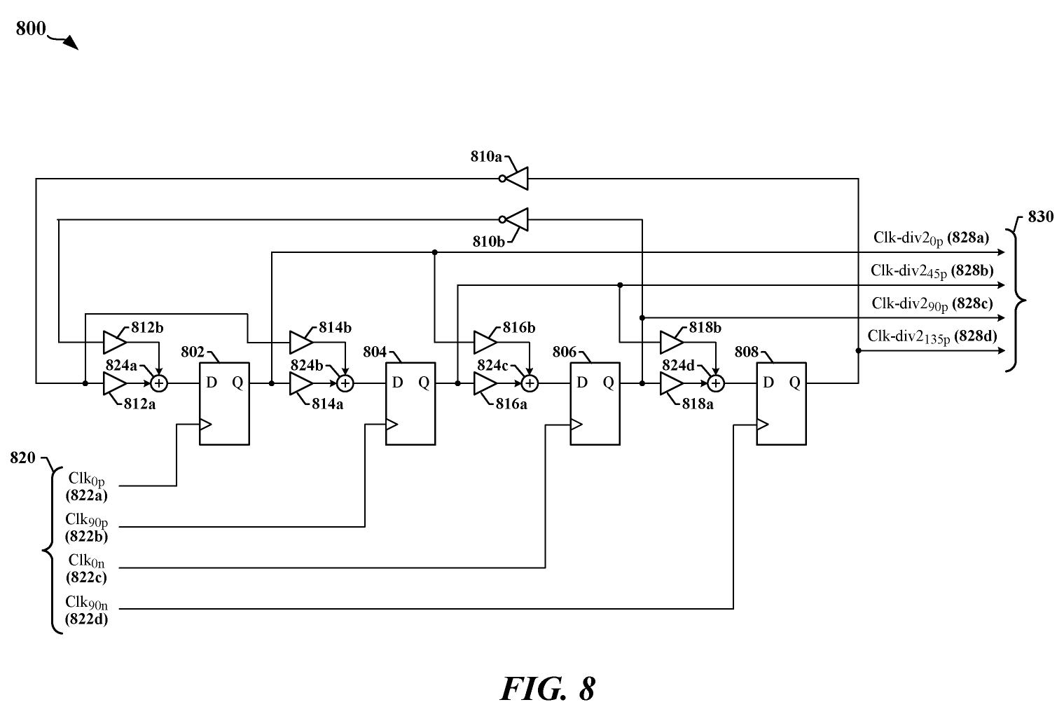

FIG. 8 illustrates a clock generator 800 that has been configured or adapted in accordance with certain aspects of this disclosure. The clock generator 800 is implemented using a single-loop divider that receives a multiphase input signal 820 and outputs a multiphase clock signal 830. Certain aspects of the multiphase clock signal 830 correspond to the delay line outputs 612 shown in the timing diagram 620 in FIG. 6 and the phase signals 718a-718d shown in the timing diagram 740 in FIG. 7. The multiphase input signal 820 includes quadrature clock signals and their complements. The clock generator 800 outputs the multiphase clock signal 830 at half the frequency of an input signal 820. Four output phase signals 828a-828d are shown in FIG. 8.

In the illustrated example, the multiphase clock signal 830 is derived from a multi-phase quarter-rate input clock signal 820. In one example, the input clock signal 820 includes complementary input phase signals. In the illustrated example, the clock generator 800 receives the Clk₀ₚ signal 822a and the Clk₀ₙsignal 822c that correspond to the differential in-phase clock signal 538 (I) shown in FIG. 5, and the Clk₉₀ₚ signal 822b and the Clk₉₀ₙsignal 822d that correspond to the differential quadrature clock signal 536 (Q).

In the illustrated example, the Clk₀ₚ signal 822a is used to clock a first latch 802, the Clk₉₀ₚ signal 822b is used to clock a second latch 804, the Clk₀ₙsignal 822c is used to clock a third latch 806, and the Clk₀ₙ signal 822d is used to clock a fourth latch 808. The output of the first latch 802 is coupled to the input of the second latch 804 through buffer 814a. The output of the second latch 804 is coupled to the input of the third latch 806 through buffer 816a. The output of the third latch 806 is coupled to the input of the fourth latch 808 through buffer 818a. The output of the fourth latch 808 is coupled to the input of the first latch 802 through a first inverter 810a and buffer 814a. The first inverter 810a causes the outputs of the latches 802-808 to oscillate at half the frequency of the Clk₀ₚ signal 808a. The outputs of the latches 802-808 drive phase signals 828a-828d.

The clock generator 800 includes feedforward paths that enable early signal transitions at the inputs to the latches 802-808. A first feedforward path couples the input of the first latch 802 to the input of the second latch 804 through buffer 814b. A second feedforward path couples the input of the second latch 804 to the input of the third latch 806 through buffer 816b. A third feedforward path couples the input of the third latch 806 to the input of the fourth latch 808 through buffer 818b. A fourth feedforward path couples the input of the fourth latch 808 to the input of the first latch 802 through a first inverter 810b and buffer 814b.

Each feedforward path causes an early transition at the input of a destination latch 802-808, before the destination latch is clocked. For example, the first feedforward path causes the input of the second latch 804 to transition to the high signaling state at the input of the second latch 804 is propagated through the second latch 804 when, for example, a rising edge occurs in the Clk₉₀ₚsignal 822b. The rising edge in the Clk₉₀ₚ signal 822b occurs one quarter clock cycle after a rising edge in the Clk₀ₚ signal 822a occurs and the high signaling state is propagated through the first latch 802. The feedforward path can reduce or eliminate the delay due to setup at the inputs of the latches 802-808.

FIG. 8 shows summers 824a-824d that combine the output of the preceding latch 802-808 with the signal provided through a corresponding feedforward path to provide the input to each latch 802-808. For example, the output of the buffer 814b in the first feedforward path is summed by 824b with the output of buffer 814a to obtain the input to the first latch 802. In certain implementations, the summers 824a-824d are embedded in each latch 802-808. In one example, each latch 802-808 may be implemented using a dual input latch. Feedforward paths can reduce the effective delay of the latches latch 802-808 through early injection of their respective input signals.

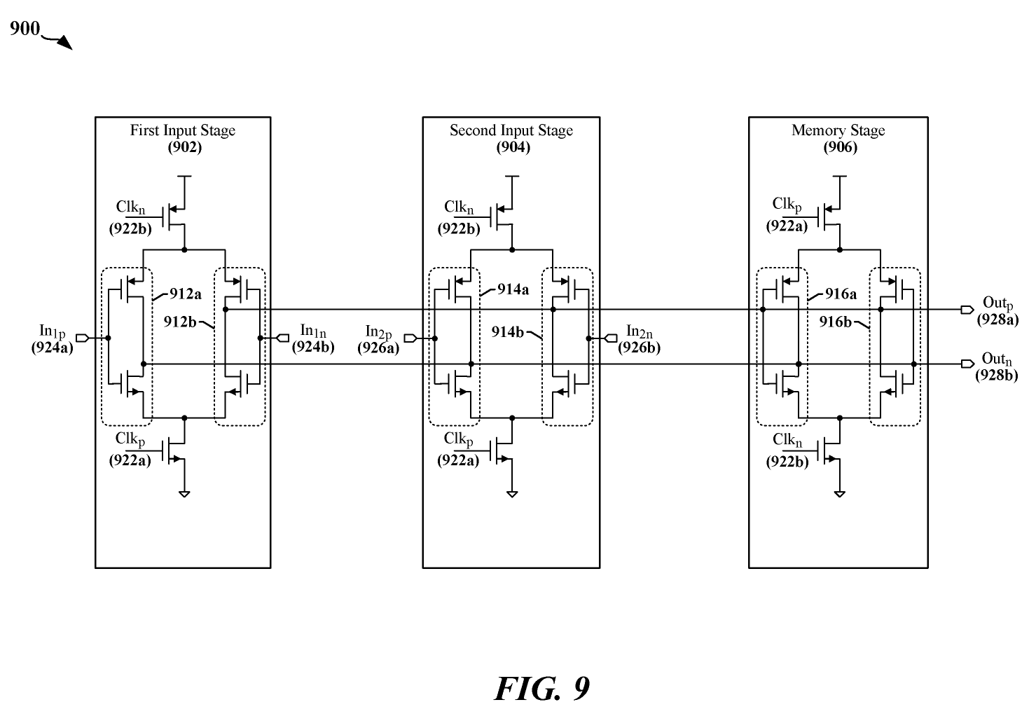

FIG. 9 illustrates an example of dual input latch 900 that may be configured in accordance with certain aspects of this disclosure. The dual input latch 900 is configured to capture the signaling state of summed differential input signals at transitions of a differential clock signal. A first latch input circuit (i.e., the first input stage 902) receives a first differential input signal that includes the In₁ₚ signal 924a and the In₁ₙ signal 924b. The In₁ₚ signal 924a controls the gates of transistors in a first CMOS inverter 912a, and the In₁ₙ signal 924b controls the gates of transistors in a second CMOS inverter 912b. A second latch input circuit (i.e., the second input stage 904) receives a first differential input signal that includes the In₂ₚ signal 926a and the In₂ₙ signal 926b. The In₂ₚ signal 926a controls the gates of transistors in a first CMOS inverter 914a, and the In₂ₙ signal 926b controls the gates of transistors in a second CMOS inverter 912b.

The differential clock signal includes the Clkₚ signal 922a and the Clkₙ signal 922b. The differential clock signal switches between a first voltage state (the “high signaling state”) when the voltage difference between the Clkₚ signal 922a and the Clkₙ signal 922b has a first value and a second voltage state (the “low signaling state”) when the difference between the Clkₚ signal 922a and the Clkₙ signal 922b has a second value. In some implementations, the amplitudes of the first and second voltages are nominally the same, but the sign is different.

In the illustrated example, the CMOS inverters 912a, 912b in the first input stage 902 may be enabled when the differential clock signal is in the first voltage state and disabled when the differential clock signal is in the second voltage state. The CMOS inverters 914a, 914b in the second input stage 904 may be enabled when the differential clock signal is in the first voltage state and disabled when the differential clock signal is in the second voltage state. When enabled, the first input stage 902 and the second input stage 904 are configured to provide a current to an output circuit (i.e., the memory stage 906). The memory stage 906 receives an input that is representative of the sum of the first and second differential input signals. In the context of the clock generator 800, the first and second differential input signals are expected to have the same signaling state when the first input stage 902 and the second input stage 904 are enabled.

The memory stage 906 is configured to drive the output of the dual input latch 900 (i.e., the Outₚ signal 928a and the Outₙ signal 928b), when enabled. The memory stage 906 is enabled when cross-coupled CMOS inverters 916a, 916b are enabled. The gates of transistors in a first CMOS inverter 916a are coupled to the drains of transistors in a second CMOS inverter 916b. The gates of the transistors in the second CMOS inverter 916b are coupled to the drains of transistors in the first CMOS inverter 916a. When enabled the CMOS inverters 916a, 916b hold the signaling state of the output of the dual input latch 900. When the CMOS inverters 916a, 916b are disabled, the first input stage 902 and the second input stage 904 cooperate to drive the output of the dual input latch 900, and define the signaling state maintained by the memory stage 906 when the cross-coupled CMOS inverters 916a, 916b are enabled.

Clock generators may be controlled using feedback that identifies timing skews between edges in clock signals and/or skew between edges in clock signals and edges in data signals. Alignment of clock and data signals is required for reliable transmission and capture of serial data. Skew and timing errors may be corrected using feedback provided by phase detectors to adjust delays in phase interpolators or phase rotators to adjust higher speed clock signals. Lower speed clock signals (i.e. divided clock signals) may then be further corrected using duty cycle correction circuits, and or phase shifting circuits.

Certain aspects of this disclosure relate to sub-rate phase detection circuits that can identify phase lock, phase skew or phase errors using information related to lower speed clock signals. In one aspect, phase detection circuits may be used to detect phase alignment, phase skew and/or phase errors that can affect serializers. Phase detection circuits may be implemented that can detect phase alignment, phase skew and/or phase errors between data and clock signals.

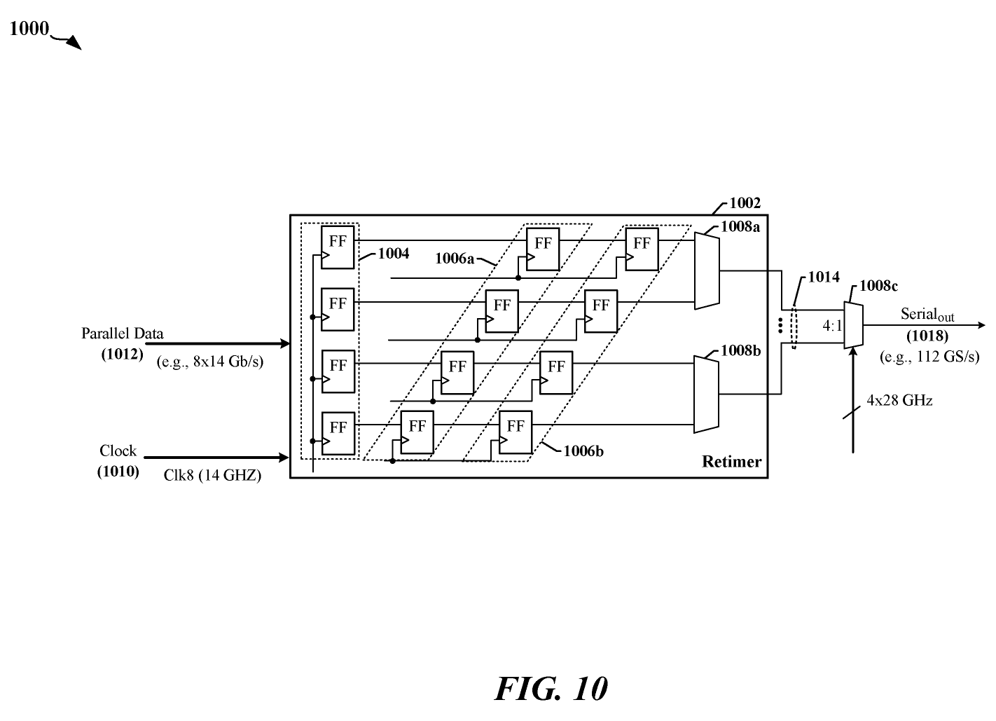

FIG. 10 illustrates a generalized example of a serializer circuit 1000 in a transmitter. The serializer circuit 1000 includes a retimer circuit 1002 that can be configured to receive a parallel data input 1012 that represents an N-bit data element. In one example, the parallel data input 1012 represents an 8-bit word. In another example, the parallel data input 1012 represents a 32-bit word. In another example, the parallel data input 1012 represents a portion of a word. In the latter example, the retimer circuit 1002 may receive a multiplexed stream of portions of the N-bit data element. In some implementations, the an N-bit data element may be multiplexed into 4-bit portions that are sequentially fed to the retimer circuit 1002.

The illustrated retimer circuit 1002 includes D flipflops 1004 that are configured to receive a parallel data input 1012. The D flipflops 1004 may be configured to align data samples with the rising edges in corresponding clock phases. Alignment can be accomplished by clocking the D flipflops 1004 with different clock phases. The output of D flipflops 1004 may be propagated through multiple stages of D flipflops, including D flipflops 1006a, 1006b. In one example, D flipflops 1006a, 1006b may be used to assemble a complete copy of a multiplexed N-bit data element in the retimer circuit 1002 before generating a corresponding serial output (i.e., Serialₒᵤₜ 1018). In another example, the D flipflops 1006a, 1006b may be used to synchronize timing of the data used to generate Serialₒᵤₜ1018. In another example, the D flipflops 1006a, 1006b may be used to buffer multiple N-bit data elements in the retimer circuit 1002. In one implementation, the retimer circuit 1002 may be configured to operate as an 8:4 multiplexer.

The outputs of the final stage D flipflops (e.g., D flipflops 1006b) may be provided to multiplexers 1008a, 1008b, 1008c that generate Serialₒᵤₜ 1018. In the illustrated example, multiplexers 1008a, 1008b may be configured to produce a 4-bit multiplexed output 1014 that is provided by the retimer circuit 1002 to a multiplexer 1008c that generates Serialₒᵤₜ 1018. In one example, Serialₒᵤₜ1018 provides retimed data at 112 giga symbols per second. (i.e., 112 GS/s). The term symbol may refer to a multi-bit element of data that is transmitted over multiple data lines in a communication link.

The illustrated retimer circuit 1002 is controlled by a multiphase input clock signal 1010. In one example, the multiphase input clock signal 1010 has a frequency of 14 GHz and includes 8 phase versions. In various implementations, the phase versions in the multiphase input clock signal 1010 are used to define the order in which data is sequenced for transmission in Serialₒᵤₜ1018 by the multiplexers 1008a, 1008b, 1008c. The capture of parallel data input 1012 by D flipflops 1004, and the propagation of data through D flipflops 1006a, 1006b may be controlled by signals derived from the multiphase input clock signal 1010 and/or from an external clock signal.

In the illustrated example, the phase versions in the multiphase input clock signal 1010 provided to the retimer circuit 1002 are expected to have the same alignment as retimed data, where retimed data may refer to the data transmitted through Serialₒᵤₜ1018. In some implementations, retimed data may be derived from the 4-bit multiplexed output 1014 and/or data that has been propagated through at least a portion of the retimer circuit 1002. Phase detection in signals clocked at higher frequencies (e.g., 112 GHz) can be complex and consume high levels of power.

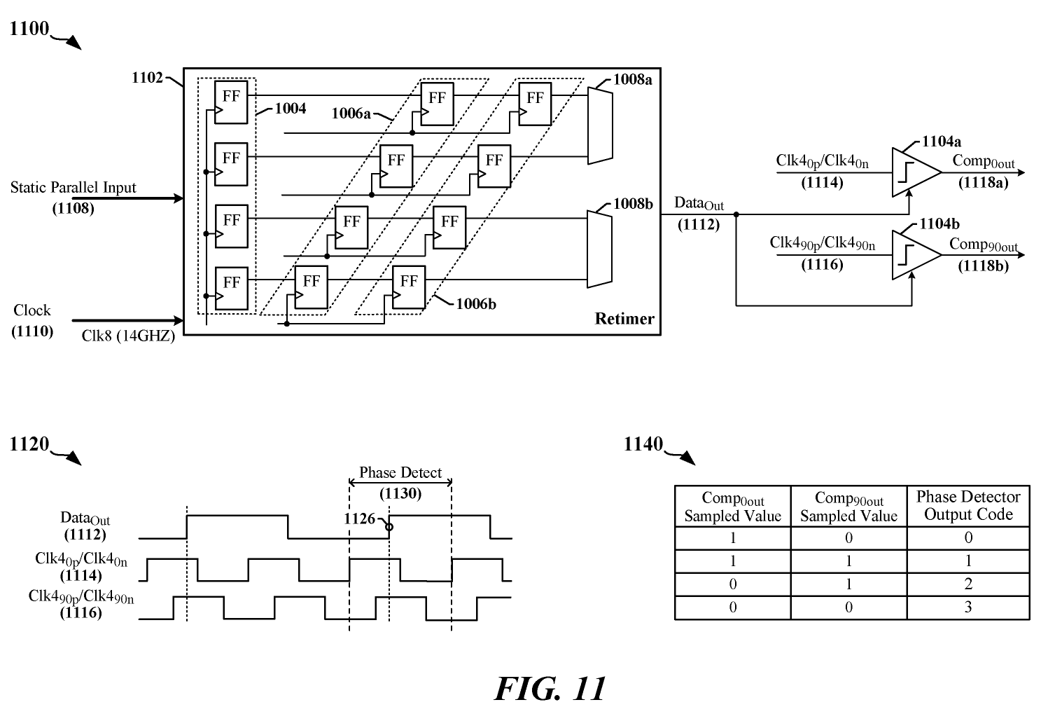

FIG. 11 illustrates an example of a phase detection circuit 1100 that may be implemented in accordance with certain aspects of this disclosure. The phase detection circuit 1100 may include a retimer circuit 1102 that is a replica of the retimer circuit used to serialize data in a transmitter. In one example, the retimer circuit 1102 corresponds in many respects to the retimer circuit 1002 illustrated in FIG. 10. The retimer circuit 1102 can be expected to perform in the same manner as the replicated retimer circuit that is provided in a data path of a serial transmitter. In certain implementations, the retimer circuit 1102 is physically located on an IC device adjacent to, or in close proximity to the replicated retimer circuit. Typically, the retimer circuit 1102 is expected to be affected by the same PVT conditions experienced by the replicated retimer circuit.

The retimer circuit 1102 receives the same multiphase input clock signal 1110 provided to control the replicated retimer circuit. However, the retimer circuit 1102 receives a static parallel input 1108, rather than the parallel data input (e.g., the parallel data input 1012 shown in FIG. 10) provided to the replicated retimer circuit. The parallel data input provided to the replicated retimer circuit can be expected to be random, or to have variable bit patterns. The static parallel input 1108 has a fixed bit pattern. The bit pattern may be configured to produce a stream of alternating binary '1' and binary '0' values in a data output signal (e.g., Data_{Out} 1112) of the retimer circuit 1102. In one example, bit values change at each bit position in the static parallel input 1108 (i.e., binary 10101010) such that the Data_{Out} signal 1112 provides an alternating signal at the frequency of the multiphase input clock signal 1110, and that is expected to have a 50% duty cycle. Other bit patterns may be used to configure the Data_{Out} signal 1112 with a duty cycle that is not 50% or a frequency that is less than the frequency of the multiphase input clock signal 1110.

In the illustrated example, the Data_{Out} signal 1112 is provided to a pair of comparator circuits 1104a, 1104b that can be configured to determine the phase relationship between the Data_{Out} signal 1112 and phases of the multiphase input clock signal 1110. In certain implementations, the comparator circuits 1104a, 1104b are implemented using differential latches. In the illustrated example, the comparator circuits 1104a, 1104b are implemented as “strong-arm” or “double-tail” comparators. In one example, the output nodes of the comparator circuits 1104a, 1104b are precharged in a first phase of an operation, an input differential pair is used to compare the voltages in a second phase of the operation and latches an output to complete the operation.

In one example, the Data_{Out} signal 1112 is provided to the clock inputs of the comparator circuits 1104a or 1104b. The differential inputs of the comparator circuits 1104a, 1104b are configured to receive complementary phases of clock signal. may be provided as a differential input signal to the inputs of the first input stage 902. The differential input of a first comparator circuit 1104a receives an in-phase differential clock signal 1114 that includes 0° shifted and 180° shifted versions of the multiphase input clock signal 1110. The differential input of a second comparator circuit 1104b receives a quadrature differential clock signal 1116 that includes 90° shifted and 270° shifted versions of the multiphase input clock signal 1110.

Referring to the timing diagram 1120, sampling edges 1126 in the Data_{Out} signal 1112 trigger the comparator circuits 1104a, 1104b such that the comparator circuits 1104a, 1104b capture the signaling state of the in-phase differential clock signal 1114 and the quadrature differential clock signal 1116. The outputs 1118a, 1118b of the comparator circuits 1104a, 1104b are expected to have the same binary value during each phase detect cycle 1130. Any difference between outputs 1118a, 1118b indicates phase lock status and/or may indicate presence of a type of phase error. A processor, controller, finite state machine or a logic circuit may be configured to an output code that may be used by a calibration or compensation circuit to correct phase errors. The table 1140 provides one example of possible comparator outputs. In the illustrated example, a phase locked transmitter is expected to generate a phase detector output code with a value of 3.

Timing skews affecting clock signals and/or data signals may be caused by a variety of sources. For example, driver circuits may introduce delays that can cause skew and timing errors. In some implementations, a communication link may be operated using different transmission clock signals in different modes of operation. Drivers may not be optimized for multiple modes of operation, including when data transmission rates can exceed 200 Gbps. In some systems, current mode logic (CML) is used to support high data rate communication, including data rates of 200 Gbps and more. Current levels are used to represent binary values in CML circuits.

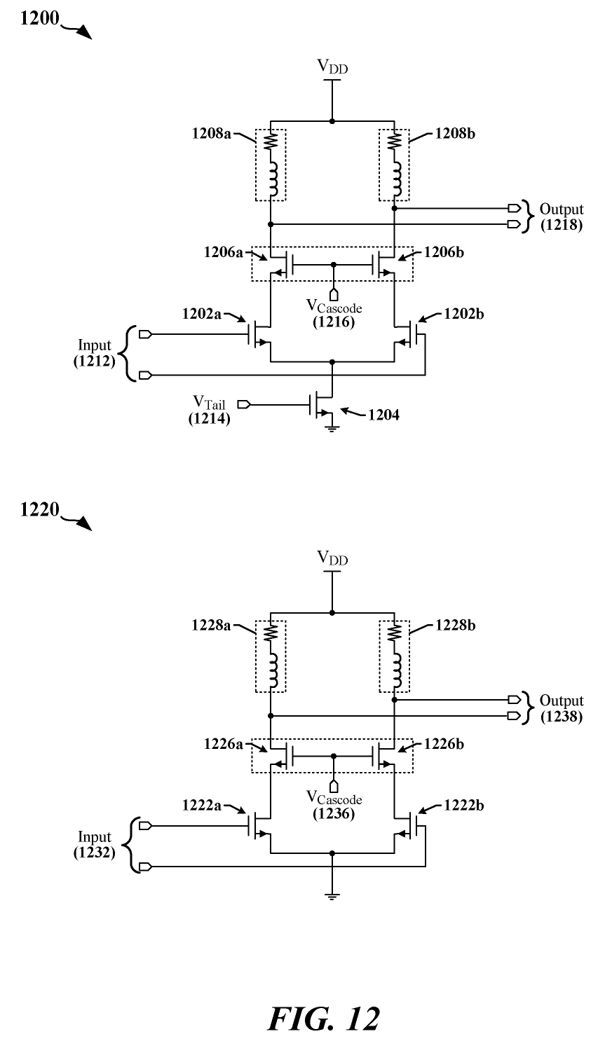

FIG. 12 illustrates two driver circuits 1200, 1220 that can be used in CML-based interface circuits. Some CML circuits use a combination of the driver circuits 1200, 1220 to optimize circuit designs. A first driver circuit 1200 includes input transistors 1202a, 1202b that are configured to receive a differential input signal 1212. Each of the complementary signals in the differential input signal 1212 is coupled to a gate of an input transistor 1202a or 1202b. The sources of the input transistors 1202a, 1202b are coupled through a common node to the drain of a biasing transistor 1204 in a tail circuit. The source of transistor 1204 is coupled to circuit ground and the gate of the biasing transistor 1204 receives a control or reference voltage (i.e., V_{Tail} 1214). V_{Tail}1214 controls the current flowing through the input transistors 1202a, 1202b and can control the swing (i.e., the amplitude) of the differential output signal 1218.

The illustrated first driver circuit 1200 is configured as a cascode circuit, where the input transistors 1202a, 1202b implement a common-source stage and a common gate stage is implemented by cascode transistors 1206a, 1206b. In other examples, the cascode transistors 1206a, 1206b may be omitted. As illustrated, each of the input transistors 1202a, 1202b is coupled to a power supply rail (i.e., V_{DD}) through a corresponding cascode transistor 1206a or 1206b and a corresponding impedance 1208a or 1208b. The drain of a first input transistor 1202a is coupled to the source of a first cascode transistor 1206a and the drain of a second input transistor 1202b is coupled to the source of a second cascode transistor 1206a. The drain of the first cascode transistor 1206a is coupled to V_{DD} through a first impedance 1208a and the drain of the second cascode transistor 1206b is coupled to V_{DD} through a second impedance 1208b. The gates of the cascode transistors 1206a, 1206b receive a cascode control voltage (i.e., V_{Cascode} 1216). The voltage level of V_{Cascode}1216 may be configured to define or control output impedance.

The second driver circuit 1220 corresponds in many respects to the first driver circuit 1220 but is implemented without a tail circuit. The second driver circuit 1220 includes input transistors 1222a, 1222b that are configured to receive a differential input signal 1232. Each of the complementary signals in the differential input signal 1232 is coupled to a gate of an input transistor 1222a or 1222b. The sources of the input transistors 1222a, 1222b are coupled through a common node to circuit ground.

The illustrated second driver circuit 1220 is configured as a cascode circuit, where the input transistors 1222a, 1222b implement a common-source stage and a common gate stage is implemented by cascode transistors 1226a, 1226b. The cascode transistors 1226a, 1226b can be used to control the swing (i.e., the amplitude) of the differential output signal 1238. As illustrated, each of the input transistors 1222a, 1222b is coupled to a power supply rail (i.e., V_{DD}) through a corresponding cascode transistor 1226a or 1226b and a corresponding impedance 1228a or 1228b. The drain of a first input transistor 1222a is coupled to the source of a first cascode transistor 1226a and the drain of a second input transistor 1222b is coupled to the source of a second cascode transistor 1226a. The drain of the first cascode transistor 1226a is coupled to V_{DD} through a first impedance 1228a and the drain of the second cascode transistor 1226b is coupled to V_{DD} through a second impedance 1228b. The gates of the cascode transistors 1226a, 1226b receive a cascode control voltage (i.e., V_{Cascode}1236) that may be configured to control the swing of the differential output signal 1238.

In some instances, the first driver circuit 1200 can exhibit greater linearity than the first driver circuit 1200 and may provide high common-mode rejection ratio (CMRR). The inclusion of the biasing transistor 1204 and cascode transistors 1206a, 1206b increases the minimum voltage level (V_{Out_min}) of the differential output signal 1218 and can limit the use of the first driver circuit 1200 in low-voltage circuits. In one example, the required minimum output voltage for the first driver circuit 1200 may be calculated as:

V_{Out_min} > 3 x V_{DS},

where V_{DS} represents the voltage between source and drain. In some implementations, the cascode transistors 1206a, 1206b may be omitted from the first driver circuit 1200 and the required minimum output voltage may be recalculated as:

In some instances, the second driver circuit 1220 can operate at higher frequencies than the first driver circuit 1200. The required minimum output voltage for the second driver circuit 1220 may be calculated as:

V_{Out_min} > 2 x V_{DS}.

However, the second driver circuit 1220 may be operated as a switch, and the cascode transistors 1206a, 1206b can be omitted. The required minimum output voltage for the second driver circuit 1220 in switch mode may be recalculated as:

V_{Out_min} > V_{DS}.

In some implementations a combination of instances of the first driver circuit 1200 and instances of the second driver circuit 1220 may be used. For example, the first driver circuit 1200 can provide better linearity and the second driver circuit 1220 can be used in lower voltage circuits.

It will be appreciated that the type and configuration of transistors used to implement the first driver circuit 1200 and/or the second driver circuit 1220 can be modified to suit specific applications or use cases. For example, the illustrated first driver circuit 1200 and second driver circuit 1220 are implemented using NMOS transistors. In other examples, these driver circuits can be implemented using a configuration of PMOS transistors or some combination of NMOS and PMOS transistors.

Certain aspects of this disclosure relate to a CML driver circuit that can be configured to operate optimally in a variety of modes. In one example, a dual-mode CML driver can be configured to provide optimal combination of output swing and linearity, as determined by a trade-off analysis. In one example, the dual-mode CML driver can be configured to provide improved linearity and robust biasing when a relatively high supply voltage is available and CML driver with a tail circuit is configured. Cascode transistors can be biased to provide a desired output impedance.

In another example, the dual-mode CML driver can be configured for tailless-like operation by modifying the bias voltage applied to a tail transistor. The tail transistor can be operated in a pseudo-tailless mode of operation by forcing the tail transistor to operate in triode mode. Triode mode is in effect when gate to drain voltage is much larger than the threshold voltage. The tail transistor acts as a small resistor when operating in triode mode. The cascode transistors control the current flowing through the input transistors when the dual-mode CML driver operates in the pseudo-tailless mode of operation.

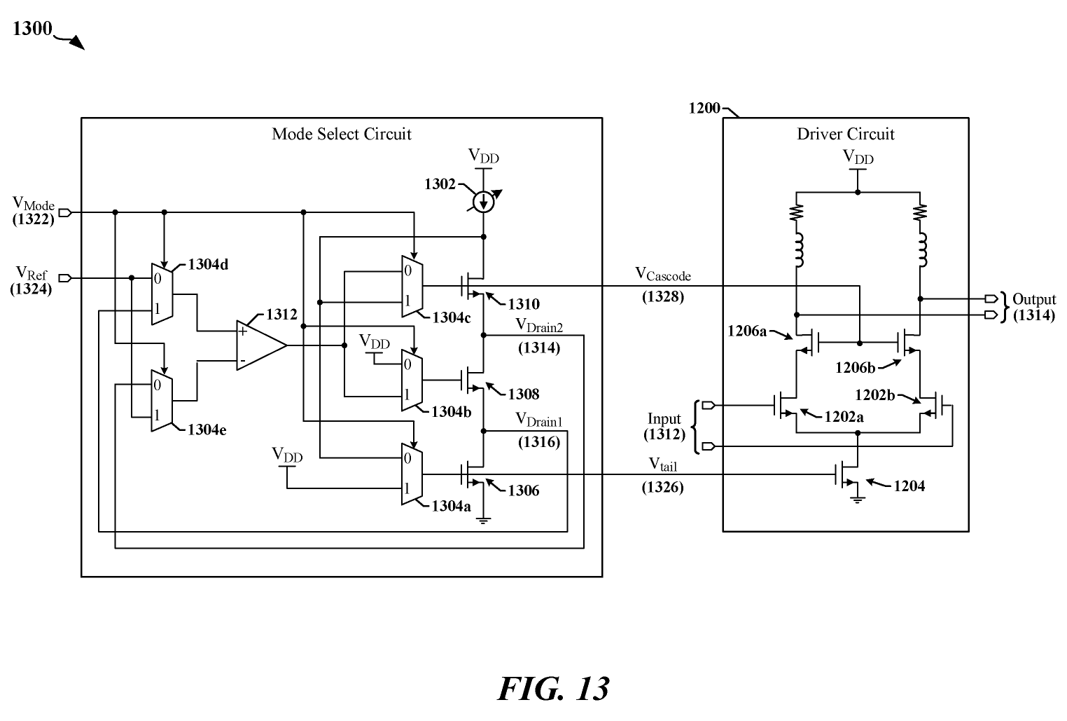

FIG. 13 illustrates a dual-mode CML driver that may be configured in accordance with certain aspects of this disclosure. the illustrated dual-mode CML driver includes a mode select circuit 1300 and the driver circuit 1200. The driver circuit 1200 is included for convenience and to facilitate the description of certain aspects that apply to a variety of driver circuits.

The mode select circuit 1300 can configure the driver circuit 1200 to operate in the mode described in relation to FIG. 12 that will be referred to herein as “the tailed mode of operation” and in a pseudo-tailless mode of operation. The mode select circuit 1300 can configure certain aspects of the tailed mode of operation and/or the pseudo-tailless mode of operation through the Vₜₐᵢₗ 1326 and/or V_{Cascode} 1328 control voltages. The mode select circuit 1300 receives a control signal (the V_{Mode} signal 1322) that indicates the desired mode of operation of the driver circuit 1200. In the illustrated example, the driver circuit 1200 is configured for the tailed mode of operation when the mode select circuit 1300 is in a low logic state and configured for the pseudo-tailless mode of operation when the mode select circuit 1300 is in a high logic state. In one example, the mode select circuit 1300 has a voltage that nominally equal to circuit ground when in the low logic state and the mode select circuit 1300 has a voltage that nominally equal to V_{DD} when in the high logic state.

The mode select circuit 1300 includes multiplexers 1304a-1304e that are controlled by the V_{Mode} signal 1322. Each of the multiplexers 1304a-1304e selects between two inputs to provide its output. Multiplexer 1304a determines whether the tail transistor 1204 receives a reference voltage or is caused to operate in triode mode. An output of multiplexer 1304a (i.e., Vₜₐᵢₗ 1326) is coupled to the gate of the tail transistor 1204 and to the gate of a replica tail transistor 1306. When the V_{Mode} signal 1322 is in the high logic state, multiplexer 1304a couples Vₜₐᵢₗ 1326 to V_{DD}, thereby causing the tail transistor 1204 to operate in triode mode. When the V_{Mode} signal 1322 is in the low logic state, the tail transistor 1204 operates in the tailed mode of operation, and multiplexer 1304a couples Vₜₐᵢₗ1326 to an output of a current source 1302 that can be configured to define the voltage at the gate of the tail transistor 1204.

The source of the replica tail transistor 1306 is coupled to circuit ground. The drain of the replica tail transistor 1306 is coupled to the output of the current source 1302 through transistors 1308 and 1310. In the tailed mode of operation, transistor 1308 is forced into triode mode by multiplexer 1304b, which couples V_{DD} to the gate of transistor 1308 when the V_{Mode} signal 1322 is in the low logic state. The voltage across the replica tail transistor 1306 is defined by transistor 1310, whereby the voltages at the drain of transistor 1306 (i.e., V_{Drain1} 1316) and the drain of transistor 1308 (i.e., V_{Drain2}1314) are largely dictated by the voltage at the output of multiplexer 1304c in the tailed mode of operation.

In the tailed mode of operation, the voltage at the gate of transistor 1310 is controlled by a feedback loop that includes the Op Amp 1312. In this feedback loop, the output of multiplexer 1304a (i.e., Vₜₐᵢₗ 1326) largely determines the current in the driver circuit. The current in the driver circuit can be adjusted by controlling the current provided by the current source 1302. It will be appreciated that the current in the driver circuit 1200 in the tailless mode of operation is determined by V_{Cascode}1328.

In the tailed mode of operation, the feedback loop causes the voltage at the source of transistor 1310 to track a reference voltage (i.e., V_{Ref} 1324) received by the mode select circuit 1300. The source of transistor 1310 is coupled to the drain of transistor 1306 in the tailed mode of operation. In the tailed mode of operation, V_{Drain2} 1314 is fed to the inverting input of the Op Amp 1312 through multiplexer 1304c. The non-inverting input of the Op Amp 1312 is coupled to V_{Ref} 1324 through multiplexer 1304d in the tailed mode of operation. The output of the Op Amp 1312 is coupled to an input of multiplexer 1304c that is selected to provide the output of multiplexer 1304c in the tailed mode of operation. The output of multiplexer 1304c is coupled to the gate of transistor 1310 and provides the cascode control voltage (i.e., V_{Cascode}1328).

When the V_{Mode} signal 1322 is in the high logic state, multiplexer 1304a couples the gate of transistor 1306 is coupled to V_{DD}, thereby causing transistor 1306 to operate in triode mode. The voltage at the gate of transistor 1308 is controlled by a feedback loop that includes the Op Amp 1312 in the pseudo-tailless mode of operation. The feedback loop causes the voltage at the source of transistor 1308 to track V_{Ref} 1324. The voltage at the source of transistor 1308 is labeled V_{Drain1} 1316 and controls the voltage at the drain of transistor 1306 in the pseudo-tailless mode of operation. In the pseudo-tailless mode of operation, V_{Drain1} 1316 is fed to the non-inverting input of the Op Amp 1312 through multiplexer 1304d. The inverting input of the Op Amp 1312 is coupled to V_{Ref} 1324 through multiplexer 1304c in the pseudo-tailless mode of operation. The output of the Op Amp 1312 is coupled to an input of multiplexer 1304b that is selected to provide the output of multiplexer 1304b in the pseudo-tailless mode of operation. The output of multiplexer 1304b is coupled to the gate of transistor 1308.

When the V_{Mode} signal 1322 is in the high logic state, the cascode transistors 1206a, 1206b control current in the driver circuit 1200. Multiplexer 1304c couples V_{Cascode}1328 to an output of the current source 1302 in the pseudo-tailless mode of operation. The source of transistor 1310 is coupled to the drain of transistor 1308 and the drain of transistor 1310 is coupled to the output of the current source 1302.

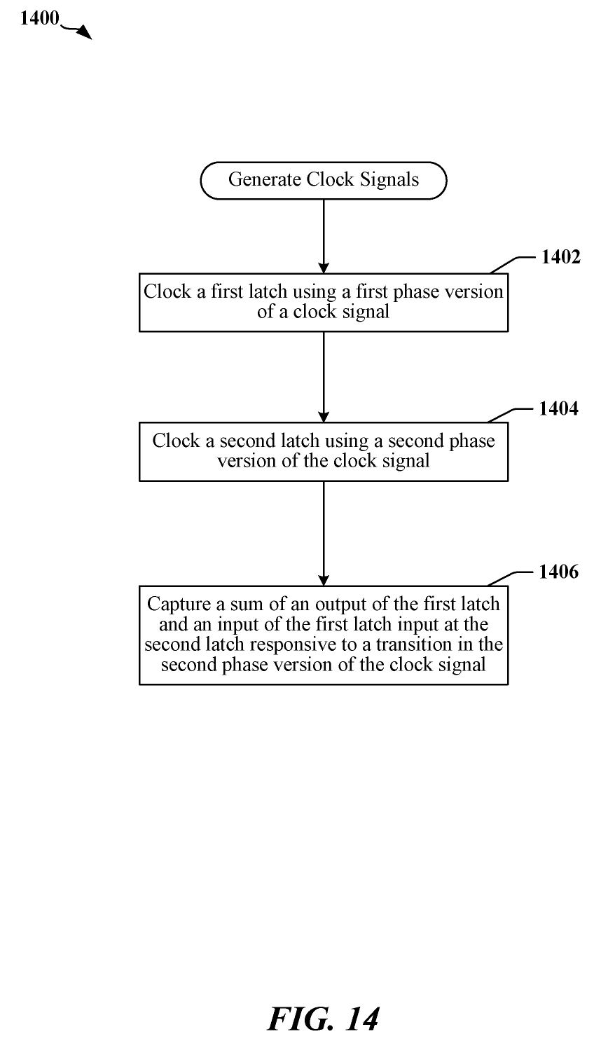

FIG. 14 is a flowchart 1400 of a method for generating clock signals in accordance with certain aspects of this disclosure. In various examples, the method may be performed using some combination of the circuits illustrated in FIGS. 8-11. In some instances, the method may be implemented by or involve one or more processors or controllers. At block 1402, a first latch may be clocked using a first phase version of a clock signal. At block 1404, a second latch may be clocked using a second phase version of the clock signal. At block 1406, a sum of an output of the first latch and an input of the first latch input is captured at the second latch responsive to a transition in the second phase version of the clock signal.

In some implementations, the first latch and second latch are included in N series-coupled latches that form a loop. A sum of an inverted output of an Nth latch and an input of the Nth latch input may be captured at the first latch responsive to a transition in the first phase version of the clock signal. Each of the N series-coupled latches comprises a dual-input latch. In one example, N is 4 and the method may be implemented using the clock generator 800 illustrated in FIG. 8.

In certain implementations, the method includes serializing a static parallel input using a replica retimer circuit configured to serialize data using the outputs of the N series-coupled latches. The method may further include using a serialized output of the replica retimer circuit to trigger comparators to sample signaling state of the first phase version of the clock signal and the second phase version of the clock signal, and determining a phase relationship between by comparing outputs of the comparators.

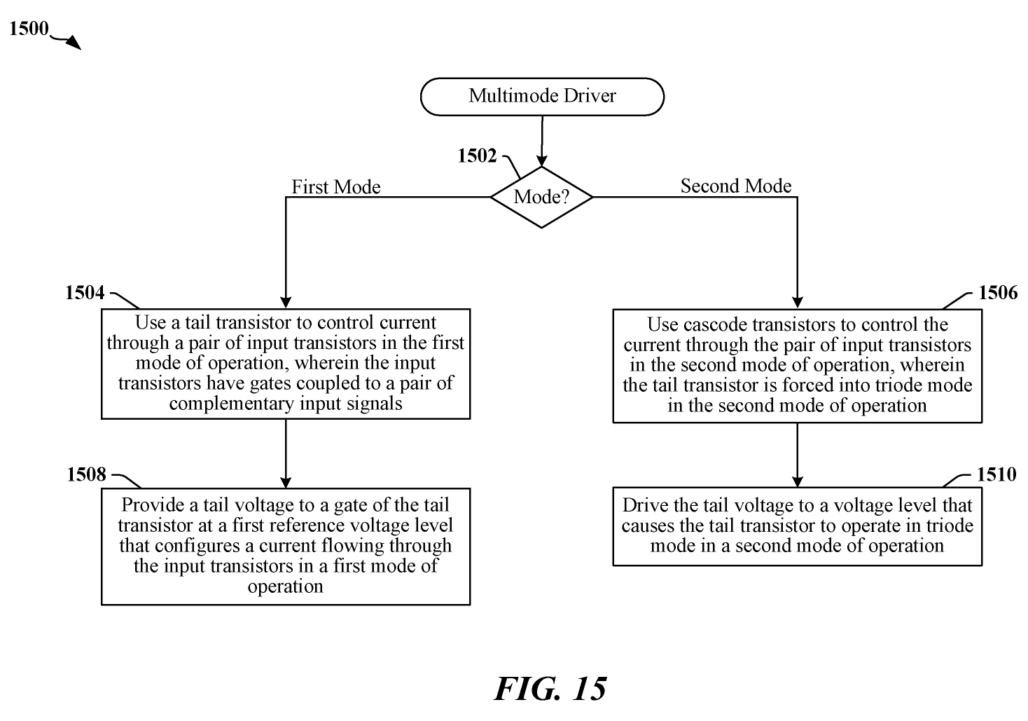

FIG. 15 is a flowchart 1500 of a method for operating a multimode driver in accordance with certain aspects of this disclosure. In various examples, the method may be performed using the circuits illustrated in FIG. 13. In some instances, the method may be implemented by or involve one or more processors or controllers. At block 1502, it may be determined whether the multimode driver is configured for a first mode of operation or a second mode of operation. When the multimode driver is configured for the first mode of operation, the method proceeds to block 1504. When the multimode driver is configured for the second mode of operation, the method proceeds to block 1506. At block 1504, a tail transistor may be used to control current through a pair of input transistors in the first mode of operation. The input transistors may have gates coupled to a pair of complementary input signals. At block 1506, cascode transistors may be used to control the current through the pair of input transistors in the second mode of operation. The tail transistor may be forced into triode mode in the second mode of operation. At block 1508, a tail voltage may be provided to a gate of the tail transistor at a first reference voltage level that configures a current flowing through the input transistors in the first mode of operation. At block 1510, the tail voltage may be driven to a voltage level that causes the tail transistor to operate in triode mode in the second mode of operation. A reference voltage may be provided to the gates of the cascode transistors in the first mode of operation. A feedback loop may be used to control the reference voltage provided to the gates of the cascode transistors in the first mode of operation.

The methods illustrated in FIG. 14 and 15 may be executed in or using an IC device. In one example, the IC device comprises an SoC. In another example, the IC device is included in one of multiple semiconductor dice mounted on a substrate. The IC device may be implemented as a chiplet in some instances. The IC device may include a clock generation circuit and multimode CML drivers.

In one example, a clock generation circuit includes latches and summing circuits. A first latch may be clocked by a first phase version of a clock signal and a second latch may be clocked by a second phase version of the clock signal. A first summing circuit may have a first input that is coupled to an output of the first latch, a second input that is coupled to an input of the first latch, and an output that is coupled to an input of the second latch.

The first latch and the second latch may be included in a plurality of series-coupled latches. Each latch in the plurality of latches may have a first input that is coupled to an output of an immediately preceding latch, and a second input that is coupled to an input of the immediately preceding latch.

In some implementations, the clock generation circuit includes N series-coupled latches that form a loop. The clock generation circuit may include a second summing circuit that has a first input coupled to an output of the Nth latch, a second input that is coupled to an input of the Nth latch, and an output that is coupled to an input of the first latch. In some instances, the second summing circuit is coupled to an inverted output of the Nth latch and an inverted input of the Nth latch, and its output may be coupled to an input of the first latch (see FIG. 8, for example). Each of the N series-coupled latches may be implemented using a dual-input latch (see FIG. 9, for example). The first summing circuit may be included in the second latch and the output of the first summing circuit may be coupled to an input of a memory stage of the second latch.

In some implementations, the clock generation circuit is configured to receive N phase versions of the clock signal. Each phase version of the clock signal may be uniquely coupled to a clocking input one of N series-coupled latches. A replica retimer circuit may be configured to receive outputs of the N series-coupled latches and a static parallel input (see FIG. 11, for example). The replica retimer circuit may be a replica of a circuit configured to serialize data using the outputs of the N series-coupled latches. A first differential latch may be configured to capture an output of the replica retimer circuit using a first phase version of the clock signal and a second differential latch may be configured to capture an output of the replica retimer circuit using a second phase version of the clock signal. The first phase version of the clock signal and the second phase version of the clock signal may be configured or selected to capture the same binary value from the output of the replica retimer circuit when the clock generation circuit is operating nominally. The N phase versions of the clock signal may include a differential in-phase version of the clock signal and a quadrature version of the clock signal. Inverters coupled in series with the N series-coupled latches may be configured or arranged to cause outputs of the N series-coupled latches to oscillate at half the frequency of the clock signal.

In another example, a multimode CML driver has a tail transistor, input transistors, cascode transistors and a mode select circuit. The tail transistor may have a source coupled to a first power rail and a gate that is configured to receive a tail voltage. The input transistors may have gates coupled to a pair of complementary input signals. The sources of the input transistors may be coupled to a drain of the tail transistor. Each cascode transistor may be coupled between a drain of a corresponding input transistor and a second power rail. The gates of the cascode transistors may be coupled together and configured to receive a cascode voltage. In response to the tail voltage at a first reference voltage level, the tail transistor may cause a current flowing through the input transistors in a first mode of operation. In response to the tail voltage at a different voltage level, the tail transistor operates in triode mode in a second mode of operation.

The driver circuit may include a mode select circuit that is configured to provide the tail voltage to the tail transistor. The mode select circuit may include a feedback loop that defines the second reference voltage in the first mode of operation. The mode select circuit may be further configured to provide a third reference voltage to the gates of the cascode transistors in the second mode of operation.

In some implementations, the mode select circuit is further configured to provide a third reference voltage to the gates of the cascode transistors in the second mode of operation. The cascode transistors may control the current flowing through the input transistors in the second mode of operation. The mode select circuit may include a feedback loop that defines the third reference voltage in the first mode of operation.

Some implementation examples are described in the following numbered clauses:
1. A driver circuit, comprising: a tail transistor having a source coupled to a first power rail and a gate that is configured to receive a tail voltage; input transistors that have gates coupled to a pair of complementary input signals, wherein the sources of the input transistors are coupled to a drain of the tail transistor; and cascode transistors, each cascode transistor being coupled between a drain of a corresponding input transistor and a second power rail, wherein the gates of the cascode transistors are coupled together and configured to receive a cascode voltage, wherein, in response to the tail voltage at a first reference voltage level, the tail transistor causes a current flowing through the input transistors in a first mode of operation, and further where, in response to the tail voltage at a different voltage level, the tail transistor operates in triode mode in a second mode of operation.
2. The driver circuit as described in clause 1, further comprising a mode select circuit configured to provide the tail voltage to the tail transistor.
3. The driver circuit as described in clause 2, wherein the mode select circuit comprises a feedback loop that defines a second reference voltage in the first mode of operation.
4. The driver circuit as described in clause 2 or clause 3, wherein the mode select circuit is further configured to provide a third reference voltage to the gates of the cascode transistors in the second mode of operation
5. The driver circuit as described in clause 4, wherein the cascode transistors control the current flowing through the input transistors in the second mode of operation.
6. The driver circuit as described in clause 4 or clause 5, wherein the mode select circuit comprises a feedback loop that defines the third reference voltage in the first mode of operation.
7. An apparatus comprising: means for controlling current through a pair of input transistors, including a tail transistor and cascode transistors; means for configuring the tail transistor, wherein the tail transistor controls the current flowing through the pair of input transistors in a first mode of operation and operates in triode mode in a second mode of operation; and means for configuring the cascode transistors, wherein the cascode transistors control the current flowing through the pair of input transistors when the tail transistor is operating in triode mode.
8. The apparatus as described in clause 7, wherein the means for configuring the tail transistor comprises a mode select circuit configured to provide a tail voltage to a gate of the tail transistor.
9. The apparatus as described in clause 8, wherein the mode select circuit is configured to couple the gate of the tail transistor to a voltage level defined by a current source in the first mode of operation.
10. The apparatus as described in any of clauses 7-9, wherein the means for configuring the cascode transistors comprises a feedback loop that is configured to define a reference voltage provided to the gates of the cascode transistors in the first mode of operation.
11. A method for operating a multimode driver, comprising: using a tail transistor to control current through a pair of input transistors in a first mode of operation, wherein the input transistors have gates coupled to a pair of complementary input signals; using cascode transistors to control the current through the pair of input transistors in a second mode of operation, wherein the tail transistor is forced into triode mode in the second mode of operation; providing a tail voltage to a gate of the tail transistor at a first reference voltage level that configures a current flowing through the input transistors in the first mode of operation; and driving the tail voltage to a voltage level that causes the tail transistor to operate in triode mode in the second mode of operation.
12. The method as described in clause 11, further comprising: providing a reference voltage to gates of the cascode transistors in the first mode of operation.

It is understood that the specific order or hierarchy of steps in the processes disclosed is an illustration of exemplary approaches. Based upon design preferences, it is understood that the specific order or hierarchy of steps in the processes may be rearranged. Further, some steps may be combined or omitted. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

What is claimed is:

1. A driver circuit, comprising:
a tail transistor having a source coupled to a first power rail and a gate that is configured to receive a tail voltage;
input transistors that have gates coupled to a pair of complementary input signals, wherein the sources of the input transistors are coupled to a drain of the tail transistor; and
cascode transistors, each cascode transistor being coupled between a drain of a corresponding input transistor and a second power rail, wherein the gates of the cascode transistors are coupled together and configured to receive a cascode voltage,
wherein, in response to the tail voltage at a first reference voltage level, the tail transistor causes a current flowing through the input transistors in a first mode of operation, and further where, in response to the tail voltage at a different voltage level, the tail transistor operates in triode mode in a second mode of operation.

2. The driver circuit of claim 1, further comprising a mode select circuit configured to provide the tail voltage to the tail transistor.

3. The driver circuit of claim 2, wherein the mode select circuit comprises a feedback loop that defines a second reference voltage in the first mode of operation.

4. The driver circuit of claim 2, wherein the mode select circuit is further configured to provide a third reference voltage to the gates of the cascode transistors in the second mode of operation.

5. The driver circuit of claim 4, wherein the cascode transistors control the current flowing through the input transistors in the second mode of operation.

6. The driver circuit of claim 4, wherein the mode select circuit comprises a feedback loop that defines the third reference voltage in the first mode of operation.

7. An apparatus comprising:
means for controlling current through a pair of input transistors, including a tail transistor and cascode transistors;
means for configuring the tail transistor, wherein the tail transistor controls the current flowing through the pair of input transistors in a first mode of operation and operates in triode mode in a second mode of operation; and
means for configuring the cascode transistors, wherein the cascode transistors control the current flowing through the pair of input transistors when the tail transistor is operating in triode mode.

8. The apparatus of claim 7, wherein the means for configuring the tail transistor comprises a mode select circuit configured to provide a tail voltage to a gate of the tail transistor.

9. The apparatus of claim 8, wherein the mode select circuit is configured to couple the gate of the tail transistor to a voltage level defined by a current source in the first mode of operation.

10. The apparatus of claim 7, wherein the means for configuring the cascode transistors comprises a feedback loop that is configured to define a reference voltage provided to gates of the cascode transistors in the first mode of operation.

11. A method for operating a multimode driver, comprising:
using a tail transistor to control current through a pair of input transistors in a first mode of operation, wherein the input transistors have gates coupled to a pair of complementary input signals;
using cascode transistors to control the current through the pair of input transistors in a second mode of operation, wherein the tail transistor is forced into triode mode in the second mode of operation;
providing a tail voltage to a gate of the tail transistor at a first reference voltage level that configures a current flowing through the input transistors in the first mode of operation; and
driving the tail voltage to a voltage level that causes the tail transistor to operate in triode mode in the second mode of operation.

12. The method of claim 11, further comprising:
providing a reference voltage to gates of the cascode transistors in the first mode of operation.

13. The method of claim 12, further comprising:
using a feedback loop to control the reference voltage provided to the gates of the cascode transistors in the first mode of operation.
